(19) United States
(12) Patent Application Publication
(10) Pub. No.: US 2015/0093879 A1
(43) Pub. Date: Apr. 2, 2015

(54) TEMPORARY ADHESIVE FOR PRODUCTION OF SEMICONDUCTOR DEVICE, AND ADHESIVE SUPPORT AND PRODUCTION METHOD OF SEMICONDUCTOR DEVICE USING THE SAME

(71) Applicant: FUJIFILM Corporation, Tokyo (JP)

(72) Inventors: Kazuhiro FUJIMAKI, Haibara-gun (JP); Ichiro KOYAMA, Haibara-gun (JP); Atsushi NAKAMURA, Haibara-gun (JP); Yu IWAI, Haibara-gun (JP); Shiro TAN, Haibara-gun (JP)

(73) Assignee: FUJIFILM CORPORATION, Tokyo (JP)

(21) Appl. No.: 14/567,471

(22) Filed: Dec. 11, 2014

Related U.S. Application Data
(63) Continuation of application No. PCT/JP2013/065102, filed on May 30, 2013.

(30) Foreign Application Priority Data
Jun. 13, 2012 (JP) 2012-134189

(51) Int. Cl. C09J 7/02; H01L 21/302; H01L 21/683

(52) U.S. Cl. CPC C09J 7/02; H01L 21/6836; H01L 21/302; H01L 2221/68381; H01L 2221/6834; H01L 2221/68318; H01L 2221/68327; C09J 175/14
USPC 438/458; 524/590; 524/558; 524/594; 428/355 R

(57) ABSTRACT

The invention is directed to a temporary adhesive for production of semiconductor device, containing (A) a polymer compound having an acid group, (B) a diluent, and (C) a solvent, an adhesive support including a substrate and an adhesive layer formed from the temporary adhesive for production of semiconductor device, and a production method of semiconductor device having a member processed including: adhering a first surface of a member to be processed to a substrate through an adhesive layer formed from the temporary adhesive for production of semiconductor device as claimed; conducting a mechanical or chemical processing on a second surface which is different from the first surface of the member to be processed to obtain the member processed; and releasing the first surface of the member processed from the adhesive layer.

### CROSS REFERENCE TO RELATED APPLICATION

This is a continuation of International Application No. PCT/JP2013/065102 filed on May 30, 2013, and claims priority from Japanese Patent Application No. 2012-134189 filed on Jun. 13, 2012, the entire disclosures of which are incorporated herein by reference.

### TECHNICAL FIELD

The present invention relates to a temporary adhesive for production of semiconductor device, and an adhesive support and a production method of semiconductor device using the same.

### BACKGROUND ART

Heretofore, in the production process of semiconductor device, for example, IC or LSI, ordinarily, a large number of IC chips are formed on a semiconductor silicon wafer and diced by dicing.

With the needs for further miniaturization and higher performance of electronic devices, further miniaturization and higher integration of IC chip mounted in the electronic device are requested, however, the high integration of the integrated circuit in the plane direction of a silicon substrate is close to the limit.

As an electrical connection method from an integrated circuit in an IC chip to an external terminal of the IC chip, a wire bonding method has been heretofore widely known. In order to reduce the size of the IC chip, in recent years, a method where a through hole is provided in a silicon substrate and a metal plug, as the external terminal is connected to the integrated circuit so as to pass through the through hole (method of forming a so-called through-silicon electrode (TSV)) is known. However, according to the method of forming a through silicon-electrode alone, the needs of higher integration for IC chip in recent years as described above are not sufficiently fulfilled.

In the light of the above, a technique of improving the integration density per unit area of the silicon substrate by making the integrated circuit in IC chip multi-layered is known. However, since the multi-layered integrated circuit increases the thickness of the IC chip, reduction in the thickness of members constituting the IC chip is required. As to the reduction in the thickness of the member, for example, reduction in the thickness of the silicon substrate has been studied and is promising not only to lead to the miniaturization of IC chip but also to save labor in a through-hole producing step of the silicon substrate in the production of through-silicon electrode.

As a semiconductor silicon wafer used in a producing process of semiconductor device, the semiconductor silicon wafer having a thickness from about 700 to 900 μm is widely known. In recent years, for the purpose of miniaturization of IC chip, it has been attempted to reduce the thickness of semiconductor silicon wafer to 200 μm or less.

However, since the semiconductor silicon wafer having the thickness of 200 μm or less is very thin and thus, a member for producing semiconductor device using the semiconductor silicon wafer as a base material is also very thin, in the case where the member is subjected to further processing or where the member is simply moved, it is difficult to support the member stably and without imparting damage to the member.

In order to solve the problem described above, a technique is known wherein a semiconductor wafer having a device provided on the surface thereof before thinning and a supporting substrate for processing are temporarily adhered with a silicone adhesive, a back surface of the semiconductor wafer is ground to make it thin, the semiconductor wafer is punched to provide a through-silicon electrode, and then the supporting substrate for processing is released from the semiconductor wafer (see Patent Document 1). It is described that according to the technique, resistance to grinding at the grind of back surface of the semiconductor wafer, heat resistance in an anisotropic dry etching step or the like, chemical resistance at plating and etching, smooth final release from the supporting substrate for processing and a low adherend contamination property are able to be achieved at the same time.

Also, as a method of supporting a wafer, a technique is known which is a method for supporting a wafer by a support layer system, wherein between the wafer and the support layer system, a plasma polymer layer obtained by a plasma deposition method is interposed as a separation layer, and an adhesion bonding between the support layer system and the separation layer is made larger than an adhesion bonding between the wafer and the separation layer so as to be easily released the wafer from the separation layer when the wafer is released from the support layer system (see Patent Document 2).

Also, a technique of performing temporary adhesion using a polyethersulfone and a viscosity imparting agent, and then releasing the temporary adhesion with heating is known (see Patent Document 3).

Also, a technique of performing temporary adhesion with a mixture composed of a carboxylic acid and an amine, and then releasing the temporary adhesion with heating is known (see Patent Document 4).

Also, a technique is known wherein a device wafer and a supporting substrate are bonded with pressure to be adhered in a state where an adhesion layer composed of a cellulose polymer and the like is heated, and then the device wafer is released from the supporting substrate by laterally sliding under heating (see Patent Document 5).

Also, an adhesion film composed of syndiotactic 1,2-polybutadiene and a photopolymerization initiator, an adhesive force of which is changed by irradiation of radiation is known (see Patent Document 6).

Further, a technique is known wherein a supporting substrate and a semiconductor wafer are temporary adhered with an adhesive composed of a polycarbonate, the semiconductor wafer is subjected to processing, and by irradiating active energy ray and then heating, the semiconductor wafer processed is released from the supporting substrate (see Patent Document 7).

Also, although it is not specifically intended to use for a temporary adhesion, a polymerizable composition containing a polymer compound having an acid group, a monomer and a radical initiator is known (see Patent Document 8).

### PRIOR ART DOCUMENT

### Patent Document

Patent Document 1: JP-A-2011-119427 (the term “JP-A” as used herein means an “unexamined published Japanese patent application”)
Patent Document 2: JP-T-2009-528688 (the term “JP-T” as used herein means a published Japanese translation of a PCT patent application)
Patent Document 3: JP-A-2011-225814
Patent Document 4: JP-A-2011-52142
Patent Document 5: JP-T-2010-506406
Patent Document 6: JP-A-2007-45939
Patent Document 7: U.S. Patent Publication No. 2011/0318938
Patent Document 8: JP-A-2005-250438

### DISCLOSURE OF THE INVENTION

### Problems that the Invention is to Solve

In the case where a surface of semiconductor wafer provided with a device (that is, a device surface of device wafer) and a supporting substrate (that is, a carrier substrate) are temporarily adhered through a layer composed of the adhesive known in Patent Document 1 or the like, the adhesion of a certain strength is required for the adhesive layer in order to stably support the semiconductor wafer.

Therefore, in the case where the whole device surface of the semiconductor wafer and the supporting substrate are temporarily adhered through the adhesive layer, when the temporary adhesion between the semiconductor wafer and the supporting substrate is made sufficient in order to support the semiconductor wafer stably and without imparting damage to the semiconductor wafer, due to the too strong temporary adhesion between the semiconductor wafer and the supporting substrate, on the other hand, a disadvantage in that the device is damaged or in that the device is released from the semiconductor wafer is likely to occur, when the semiconductor wafer is released from the supporting substrate.

Also, the method of forming as a separation layer, a plasma polymer layer by a plasma deposition method between the wafer and the support layer system as in Patent Document 2 in order to prevent that the adhesion between the wafer and the support layer system becomes too strong has problems (1) in that the equipment cost for performing the plasma deposition method is ordinarily high, (2) in that the layer formation by the plasma deposition method takes time for vacuumization in the plasma apparatus and deposition of monomer, and (3) in that even when the separation layer composed of a plasma polymer layer is provided, it is not easy to control the adhesion bonding in such a manner that the wafer is easily released from the separation layer in the case of releasing the supporting of wafer, while, on the other hand, the adhesion bonding between the wafer and the separation layer maintains sufficiently in the case of supporting the wafer subjected to the processing.

Also, the method of releasing the temporary adhesion with heating as described in Patent Documents 3, 4 and 5, a disadvantage in that the device is damaged is likely to occur, when the semiconductor wafer is released.

Also, in the method of releasing the temporary adhesion by irradiation of active energy ray as described in Patent Documents 6 and 7, it is necessary to use a supporting substrate which transmits the active energy ray.

The invention has been made in the light of the background described above, and an object of the invention is to provide a temporary adhesive for production of semiconductor device, which not only can temporarily support a member to be processed (for example, a semiconductor wafer) firmly and easily when the member to be processed is subjected to a mechanical or chemical processing, but also can easily release the temporary support for the member processed without imparting damage to the member processed, and an adhesive support and a production method of semiconductor device using the same.

### Means for Solving the Problems

As a result of the intensive investigations to solve the problems described above, the inventors have found that when a composition containing a polymer compound having an acid group and a diluent is used as a temporary adhesive in a temporary adhesion step of a semiconductor wafer and a supporting substrate, not only a member to be processed can be temporarily supported firmly, but also after processing the member to be processed, the temporary support for the member processed can be easily released by bringing the adhesive layer into contact with an aqueous alkali solution or a release solvent without conducting heating or irradiation of active light or radiation as conducting in the prior art described above, although the reason for this is not quite clear, to complete the invention. Specifically, the invention includes the following items.

(1) A temporary adhesive for production of semiconductor device containing (A) a polymer compound having an acid group, (B) a diluent, and (C) a solvent.
(2) The temporary adhesive for production of semiconductor device as described in (1) above, wherein the polymer compound (A) is a polyurethane resin having a carboxylic acid group, a (meth)acrylic polymer having a carboxylic acid group or a novolak resin having a carboxylic acid group.
(3) The temporary adhesive for production of semiconductor device as described in (1) or (2) above, which further contains (D) a compound which generates a radical or an acid by irradiation of active light or radiation.
(4) The temporary adhesive for production of semiconductor device as described in any one of (1) to (3) above, which further contains (E) a compound which generates a radical or an acid by heat.
(5) The temporary adhesive for production of semiconductor device as described in (4) above, wherein the compound (E) is an organic peroxide.
(6) The temporary adhesive for production of semiconductor device as described in any one of (3) to (5) above, wherein the diluent (B) is a reactive compound which is capable of being crosslinked by an action of a radical or an acid.
(7) The temporary adhesive for production of semiconductor device as described in any one of (1) to (6) above, which is for forming a through-silicon electrode.
(8) An adhesive support comprising a substrate and on the substrate an adhesive layer formed from the temporary adhesive for production of semiconductor device as described in any one of (1) to (7) above.
(9) A production method of semiconductor device having a member processed comprising a step of adhering a first surface of a member to be processed to a substrate through an adhesive layer formed from the temporary adhesive for production of semiconductor device as described in any one of (1) to (7) above,

a step of conducting a mechanical or chemical processing on a second surface which is different from the first surface of the member to be processed to obtain the member processed, and

a step of releasing the first surface of the member processed from the adhesive layer.

(10) The production method of semiconductor device as described in (9) above, which further comprises a step of irradiating active light or radiation, or heat to a surface of the adhesive layer which is to be adhered to the first surface of a member to be processed, before the step of adhering a first surface of a member to be processed to a substrate through the adhesive layer.
(11) The production method of semiconductor device as described in (9) or (10) above, which further comprises a step of heating the adhesive layer at a temperature from 50 to 300° C., after the step of adhering a first surface of a member to be processed to a substrate through the adhesive layer and before the step of conducting a mechanical or chemical processing on a second surface which is different from the first surface of the member to be processed to obtain the member processed.
(12) The production method of semiconductor device as described in any one of (9) to (11) above, wherein the step of releasing the first surface of the member processed from the adhesive layer include a step of bringing the adhesive layer into contact with an aqueous alkali solution or a release solvent.
(13) The production method of semiconductor device as described in (12) above, wherein the aqueous alkali solution contains a surfactant in an amount from 0.1 to 20% by weight based on a total weight of the aqueous alkali solution.
(14) The production method of semiconductor device as described in (12) above, wherein the release solvent is acetone, anisole, cyclohexanone, ethanolamine, hexane, N-methyl-2-pyrrolidone or a fluorine-based solvent.

### Advantage of the Invention

According to the invention, a temporary adhesive for production of semiconductor device, which not only can temporarily support a member to be processed (for example, a semiconductor wafer) firmly and easily when the member to be processed is subjected to a mechanical or chemical processing, but also can release the temporary support for the member processed without imparting damage to the member processed, and an adhesive support and a production method of semiconductor device using the same can be provided.

### BRIEF DESCRIPTION OF THE DRAWING

FIG. 1A and FIG. 1B are a schematic cross-sectional view illustrating temporary adhesion of an adhesive support and a device wafer and a schematic cross-sectional view showing a state in which the device wafer temporarily adhered by the adhesive support is thinned, respectively.

FIG. 2 is a schematic cross-sectional view illustrating release of a temporary adhering state between a conventional adhesive support and a device wafer.

FIG. 3A shows a schematic cross-sectional view illustrating exposure of the adhesive support, and FIG. 3B shows a schematic top view of a mask.

FIG. 4A shows a schematic cross-sectional view of the adhesive support subjected to pattern exposure, and FIG. 4B shows a schematic top view of the adhesive support subjected to pattern exposure.

FIG. 5 shows a schematic cross-sectional view illustrating irradiation of active light or radiation, or heat to the adhesive support.

### MODE FOR CARRYING OUT THE INVENTION

Embodiments of the invention will be described in detail hereinafter.

In the description of a group (atomic group) in the specification, when the group is described without specifying whether the group is substituted or unsubstituted, the group includes both a group (atomic group) having no substituent and a group (atomic group) having a substituent. For example, “an alkyl group” includes not only an alkyl group which has no substituent (an unsubstituted alkyl group) but also an alkyl group which has a substituent (a substituted alkyl group).

In the specification, the term “active light” or “radiation” includes, for example, visible light, an ultraviolet ray, a far ultraviolet ray, an electron beam and an X-ray. Also, the term “light” as used in the invention means active light or radiation.

Also, the term “exposure” in the specification includes, unless otherwise specified, not only exposure by a mercury lamp, an ultraviolet ray, a far ultraviolet ray represented by an excimer laser, an X-ray, EUV light or the like, but also drawing by a particle ray, for example, an electron beam or an ion beam.

Also, in the specification, the term “(meth)acrylate” represents both or either of acrylate and methacrylate, the term “(meth)acryl” represents both or either of acryl and methacryl, and the term “(meth)acryloyl” represents both or either of acryloyl and methacryloyl. Also, in the specification, the terms “monomer” and “monomer” have the same meaning. A monomer according to the invention is distinguished from an oligomer and a polymer, and means a compound having a weight average molecular weight of 2,000 or less. In the specification, a polymerizable compound indicates a compound having a polymerizable group, and may be a monomer or a polymer. The polymerizable group denotes a group which is involved in a polymerization reaction.

In the embodiments described below, the member or the like described in the drawing already referred to is indicated by the same or corresponding symbol in the figure and its description is simplified or omitted.

The temporary adhesive for production of semiconductor device (hereinafter, also simply referred to as a “temporary adhesive”) according to the invention contains (A) a polymer compound having an acid group, (B) a diluent, and (C) a solvent.

In accordance with the temporary adhesive for production of semiconductor device according to the invention, a temporary adhesive for production of semiconductor device which not only can temporarily support a member to be processed firmly and easily when the member to be processed is subjected to a mechanical or chemical processing, but also can release the temporary support for the member processed without imparting damage to the member processed can be obtained.

The temporary adhesive for production of semiconductor device according to the invention is preferred for forming a through-silicon electrode. The formation of through-silicon electrode will be described in detail later.

Hereinafter, the components which the temporary adhesive for production of semiconductor device according to the invention contains will be described in detail.

### (A) Polymer Compound Having Acid Group Structure

The temporary adhesive according to the invention contains (A) a polymer compound having an acid group. By incorporating the polymer compound having an acid group (A) into the temporary adhesive, the temporary support for the member processed can be easily released without imparting damage to the member processed when an aqueous alkali solution or a release solvent is used.

As the polymer compound, a (meth)acrylic polymer, a polyurethane resin, a polyvinyl alcohol resin, a polyvinyl butyral resin, a polyvinyl formal resin, a polyamide resin, a polyester resin, an epoxy resin and a novolac resin are used. In particular, a (meth)acrylic polymer, a polyurethane resin, a novolac resin, a polyvinyl butyral resin and a polyester resin are preferred, and a (meth)acrylic polymer, a polyurethane resin and a novolac resin are more preferred. From the standpoint of more improving the adhesion property, a polyurethane resin and a novolac resin are still more preferred.

The “(meth)acrylic polymer” as used in the invention means a copolymer containing as a polymerization component, (meth)acrylic acid or a (meth)acrylic acid derivative, for example, a (meth)acrylate (including, for example, an alkyl ester, an aryl ester and an allyl ester), (meth)acrylamide or a (meth)acrylamide derivative.

The term “polyurethane resin” as used herein means a polymer formed by a condensation reaction of a compound having two or more isocyanate groups and a compound having two or more hydroxy groups.

As preferred examples of the polyurethane resin, polyurethane resins described in Paragraph Nos. [0099] to [0210] of JP-A-2007-187836, Paragraph Nos. [0019] to [0100] of JP-A-2008-276155, Paragraph Nos. [0018] to [0107] of JP-A-2005-250438 and Paragraph Nos. [0021] to [0083] of JP-A-2005-250158 are exemplified.

The “novolac resin” means a polymer produced by a condensation reaction of a phenol (for example, phenol or cresol) with an aldehyde (for example, formaldehyde). Further, it also includes a polymer in which a substituent is introduced, for example, by a method of reacting a different compound with the remaining hydroxy group.

As preferred examples of the novolac resin, a novolac resin, for example, a phenol formaldehyde resin, a m-cresol formaldehyde resin, a p-cresol formaldehyde resin, a m-/p-mixed cresol formaldehyde resin or a phenol/cresol (may be any of m-, p-, and m-/p-mixed) mixed formaldehyde resin is exemplified. A novolac resin having a weight average molecular weight from 500 to 20,000 and a number average molecular weight from 200 to 10,000 is preferred. In the invention, a hydroxy group in the novolac resin (that is, a phenolic hydroxy group) can be regarded as an acid group.

Also, a compound in which a substituent is introduced by reacting a different compound with a hydroxy group of the novolac resin can be preferably used. In the case where substituents having no acid group are introduced by reacting different compounds with the whole hydroxy groups of a novolac resin, it is necessary to introduce an acid group by further reacting with a different compound.

The acid group in the polymer compound (A) means ordinarily a substituent having pKa of 14 or less, preferably a substituent having pKa of 12 or less, and most preferably a substituent having pKa of 11 or less. Specific examples thereof includes a carboxylic acid group, a sulfonic acid group, a phosphonic acid group, a phosphoric acid group, a sulfonamido group and a phenolic hydroxy group.

As the acid group in the polymer compound (A), a carboxylic acid group, a sulfonic acid group, a phosphonic acid group, a phosphoric acid group or a sulfonamido group is exemplified, and a carboxylic acid group is particularly preferred.

A part of the acid groups in the polymer compound (A) may be neutralized with a basic compound. As the basic compound, a compound containing a basic nitrogen atom, an alkali metal hydroxide and a quaternary ammonium salt of an alkali metal are exemplified.

The polymer compound (A) is preferably a polyurethane resin having a carboxylic acid group, a (meth)acrylic polymer having a carboxylic acid group or a novolak resin having a carboxylic acid group.

The polymer compound (A) preferably contains a repeating unit having an acid group. As the repeating unit having an acid group, a repeating unit derived from (meth)acrylic acid or a repeating unit represented by formula (I) shown below is preferably used.

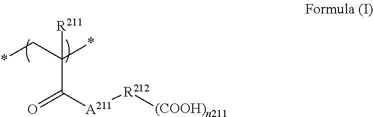

In formula (I), R²¹¹ represents a hydrogen atom or a methyl group, R²¹² represents a single bond or an (n₂₁₁+1) valent connecting group, A²¹¹ represents an oxygen atom or —NR²¹³—, R²¹³ represents a hydrogen atom or a monovalent hydrocarbon group having from 1 to 10 carbon atoms, and n₂₁₁ represents an integer from 1 to 5.

The connecting group represented by R²¹² in formula (I) is constructed from a hydrogen atom, a carbon atom, an oxygen atom, a nitrogen atom, a sulfur atom and a halogen atom and a number of atoms included is preferably from 1 to 80. Specific examples of the connecting group include an alkylene group, a substituted alkylene group, an arylene group and a substituted arylene group. The connecting group may have a structure wherein a plurality of such divalent groups is connected to each other via any of an amido bond, an ether bond, a urethane bond, a urea bond and an ester bond. R²¹² is preferably a single bond, an alkylene group, a substituted alkylene group or a structure where a plurality of an alkylene group and/or a substituted alkylene group is connected to each other via any of an amido bond, an ether bond, a urethane bond, a urea bond and an ester bond, particularly preferably a single bond, an alkylene group having from 1 to 5 carbon atoms, a substituted alkylene group having from 1 to 5 carbon atoms or a structure where a plurality of an alkylene group having from 1 to 5 carbon atoms and/or a substituted alkylene group having from 1 to 5 carbon atoms is connected to each other via any of an amido bond, an ether bond, a urethane bond, a urea bond and an ester bond, and most preferably a single bond, an alkylene group having from 1 to 3 carbon atoms, a substituted alkylene group having from 1 to 3 carbon atoms or a structure where a plurality of an alkylene group having from 1 to 3 carbon atoms and/or a substituted alkylene group having from 1 to 3 carbon atoms is connected to each other via any of an amido bond, an ether bond, a urethane bond, a urea bond and an ester bond.

Examples of the substituent which the connecting group represented by R²¹² may have include a monovalent non-metallic atomic group exclusive of a hydrogen atom, for example, a halogen atom (e.g., —F, —Br, —Cl or —I), a hydroxy group, a cyano group, an alkoxy group, an aryloxy group, a mercapto group, an alkylthio group, an arylthio group, an alkylcarbonyl group, an arylcarbonyl group, a carboxyl group and a conjugate base group thereof, an alkoxycarbonyl group, an aryloxycarbonyl group, a carbamoyl group, an aryl group, an alkenyl group or an alkynyl group.

R²¹³ is preferably a hydrogen atom or a hydrocarbon group having from 1 to 5 carbon atoms, more preferably a hydrogen atom or a hydrocarbon group having from 1 to 3 carbon atoms, and particularly preferably a hydrogen atom or a methyl group.

n₂₁₁ is preferably from 1 to 3, more preferably 1 or 2, and particularly preferably 1.

A ratio (% by mole) of the repeating unit having an acid group in the total repeating units of the polymer compound (A) is preferably from 1 to 70% in view of releasing property. Considering good compatibility between the releasing property and the adhesion property, it is more preferably from 5 to 60%, and particularly preferably from 10 to 50%.

It is preferred that the polymer compound (A) further contain a crosslinkable group. The term “crosslinkable group” as used herein means a group capable of crosslinking the polymer compound (A) typically by irradiation of active light or radiation or by an action of a radical or an acid. The crosslinkable group is not particularly limited as long as it has such a function, and it is preferably a functional group capable of undergoing an addition polymerization reaction. The functional group capable of undergoing an addition polymerization reaction includes, for example, an ethylenically unsaturated bond group, an amino group and an epoxy group. Also, the crosslinkable group may be a functional group capable of generating a radical by irradiation of active light or radiation, and such a crosslinkable group includes, for example, a thiol group and a halogen atom. Among them, the ethylenically unsaturated bond group is preferred as the crosslinkable group. The ethylenically unsaturated bond group preferably includes a styryl group, a (meth)acryloyl group and an allyl group.

In the polymer compound (A) having a crosslinkable group, for example, a free radical (a polymerization initiating radical or a propagating radical in the process of polymerization of the polymerizable compound) is added to the crosslinkable group to cause addition polymerization between the polymers directly or through a polymerization chain of the polymerizable compound and as a result, crosslinking is formed between the polymer molecules to effect curing. Alternatively, an atom (for example, a hydrogen atom on the carbon atom adjacent to the functional crosslinkable group) in the polymer is withdrawn by a free radical to produce a polymer radical and the polymer radicals combine with each other to form crosslinking between the polymer molecules to effect curing.

In the case where the polymer compound (A) contains a crosslinkable group, it is preferred that the polymer compound (A) contains a repeating unit having the crosslinkable group.

The content of the crosslinkable group (content of radical-polymerizable unsaturated double bond determined by iodine titration) in the polymer compound (A) is preferably from 0.01 to 10.0 mmol, more preferably from 0.05 to 9.0 mmol, particularly preferably from 0.1 to 8.0 mmol, per g of the polymer compound (A).

The polymer compound (A) (particularly, a (meth)acrylic polymer) may contain a repeating unit derived from alkyl (meth)acrylate or aralkyl (meth)acrylate, a repeating unit derived from (meth)acrylamide or a derivative thereof, a repeating unit derived from of α-hydroxymethyl acrylate or a repeating unit derived from a styrene derivative, in addition to the repeating unit having an acid group and the repeating unit having a crosslinkable group described above. The alkyl group in the alkyl (meth)acrylate is preferably an alkyl group having from 1 to 5 carbon atoms or an alkyl group having from 2 to 8 carbon atoms and the substituent described above, and more preferably a methyl group. The aralkyl (meth)acrylate includes, for example, benzyl (meth)acrylate. The (meth)acrylamide derivative includes, for example, N-isopropylacrylamide, N-phenylmethacrylamide, N-(4-methoxycarbonylphenyl)methacrylamide, N,N-dimethylacrylamide and morpholinoacrylamide. The α-hydroxymethyl acrylate includes, for example, ethyl α-hydroxymethyl acrylate and cyclohexyl α-hydroxymethyl acrylate. The styrene derivative includes, for example, styrene and 4-tert-butylstyrene.

Also, the polymer compound (A) preferably contains a hydrophilic group. The hydrophilic group contributes to impart the releasing property to the temporary adhesive. The coexistence of the crosslinkable group and the hydrophilic group in the polymer compound (A) further enables good compatibility between the releasing property and the adhesion property.

The hydrophilic group which the polymer compound (A) may contain includes, for example, a hydroxy group, an alkylene oxide structure, an amino group, an ammonium group, an amido group and a sulfo group, and among them, an alkylene oxide structure containing from 1 to 9 alkylene oxide units each having 2 or 3 carbon atoms is preferred. In order to impart the hydrophilic group to the polymer compound (A), for example, copolymerization of a monomer having the hydrophilic group is performed in the synthesis of the polymer compound (A).

The weight average molecular weight (Mw) of the polymer compound (A) is preferably 2,000 or more, more preferably from 2,000 to 50,000, in terms of polystyrene according to a GPC method, and the number average molecular weight (Mn) of the polymer compound (A) is preferably 1,000 or more, more preferably from 1,000 to 30,000, in terms of polystyrene according to a GPC method. The polydispersity (weight average molecular weight/number average molecular weight) is preferably from 1.1 to 10.

The GPC method is based on a method using HLC-8020GPC (produced by Tosoh Corp.), TSKgel Super HZM-H, TSKgel Super HZ4000 and TSKgel Super HZ2000 (produced by Tosoh Corp., 4.6 mm ID×15 cm) as columns, and THF (tetrahydrofuran) as a eluent.

The polymer compounds (A) may be used individually or in combination of two or more thereof. The content of the polymer compound (A) is preferably from 5 to 75% by weight, more preferably from 10 to 70% by weight, still more preferably from 10 to 60% by weight, based on the total solid content of the temporary adhesive from the standpoint of good adhesion strength and good releasing property.

### (B) Diluent

The temporary adhesive according to the invention contains (B) a diluent. The diluent is typically a non-volatile compound which does not correspond to the polymer compound (A) and a compound capable of reducing the content based on the solid content of the temporary adhesive.

By incorporating the diluent into the temporary adhesive, an adherence property and a tacking property are imparted. The diluent is preferably that having good compatibility with the polymer compound (A). The diluent (B) is not particularly limited and includes, for example, an adipic acid derivative, an azelaic acid derivative, a benzoic acid derivative, a citric acid derivative, an epoxy derivative, a glycol derivative, a hydrocarbon and a derivative thereof, an oleic acid derivative, a phosphoric acid derivative, a phthalic acid derivative, a polyester, a ricinoleic acid derivative, a sebacic acid derivative, a stearic acid derivative, a sulfonic acid derivative, a terpene and a derivative thereof, and a trimellitic acid derivative described in Kobunshi Daijiten (Polymer Dictionary), First Edition, Maruzen Co., Ltd. (1994), pages 211 to 220, and among them, an adipic acid derivative, a phthalic acid derivative, a citric acid derivative and a glycol derivative are preferred.

As the adipic acid derivative, for example, bis(2-ethylhexyl)adipate, bis(isononyl)adipate, bis(isodecyl)adipate or bis(2-butoxyethyl)adipate is preferably used. As the phthalic acid derivative, for example, dioctyl phthalate or didodecyl phthalate is preferably used. As the citric acid derivative, for example, tributyl citrate is preferably used. As the glycol derivative, for example, a polyethylene glycol, a polypropylene glycol (monool type or diol type) or a polypropylene glycol (monool type or diol type) is preferably used.

Also, it is preferred to use a reactive compound having a crosslinkable group, as the diluent (B). The term “crosslinkable group” as used herein means a group capable of crosslinking typically by irradiation of active light or radiation or by an action of a radical or an acid. In particular, the diluent (B) preferably has a group capable of crosslinking (undergoing a crosslinking reaction) by an action of a radical or an acid (in other words, the diluent (B) is preferably a reactive compound capable of crosslinking by an action of a radical or an acid).

The reactive compound having a crosslinkable group is a compound different from the polymer compound (A) described above. The reactive compound having a crosslinkable group is typically a low molecular weight compound, preferably a low molecular weight compound having a molecular weight of 2,000 or less, more preferably a low molecular weight compound having a molecular weight of 1,500 or less, and still more preferably a low molecular weight compound having a molecular weight of 900 or less. The molecular weight of the compound is ordinarily 100 or more.

By using such a reactive compound as the diluent (B), for example, when pattern exposure is conducted to the adhesive layer of adhesive support, the crosslinking reaction of crosslinkable compound proceeds in the exposed area to provide a high adhesive region and a low adhesive region in the adhesive layer, as described later.

Also, for example, when active light or radiation, or heat is irradiated to the adhesive layer of adhesive support before adhering the adhesive support to a member to be processed, the crosslinking reaction of crosslinkable compound proceeds to form the adhesive layer in which the adhesion property decreases from the inner surface on the substrate side to the outer surface. Specifically, the adhesion property of the adhesive layer to the member to be processed can be decreased while maintaining high adhesion property between the substrate and the adhesive layer in the adhesive support.

The crosslinkable group is preferably, for example, a functional group capable of undergoing an addition polymerization reaction. The functional group capable of undergoing an addition polymerization reaction includes, for example, an ethylenically unsaturated bond group, an amino group and an epoxy group. Also, the crosslinkable group may be a functional group capable of generating a radical by irradiation of light, and such a crosslinkable group includes, for example, a thiol group and a halogen atom. Among them, the ethylenically unsaturated bond group is preferred as the crosslinkable group. The ethylenically unsaturated bond group preferably includes a styryl group, a (meth)acryloyl group and an allyl group.

The reactive compound having a crosslinkable group includes a radical polymerizable compound (B1) and an ionic polymerizable compound (B2).

The radical polymerizable compound includes, for example, a (meth)acrylamide compound having from 3 to 35 carbon atoms (B11), a (meth)acrylate compound having from 4 to 35 carbon atoms (B12), an aromatic vinyl compound having from 6 to 35 carbon atoms (B13), a vinyl ether compound having from 3 to 20 carbon atoms (B14) and other radical polymerizable compound (B15). The radical polymerizable compounds (B1) may be used individually or in combination of two or more thereof. Also, a polymerization inhibitor, for example, hydroquinone or methyl ether hydroquinone may be used together, if desired.

The (meth)acrylamide compound having from 3 to 35 carbon atoms (B11) include, for example, (meth)acrylamide, N-methyl(meth)acrylamide, N-ethyl(meth)acrylamide, N-propyl(meth)acrylamide, N-n-butyl(meth)acrylamide, N-tert-butyl(meth)acrylamide, N-butoxymethyl(meth)acrylamide, N-isopropyl(meth)acrylamide, N-methylol(meth)acrylamide, N,N-dimethyl(meth)acrylamide, N,N-diethyl(meth)acrylamide and (meth)acryloylmorpholine.

The (meth)acrylate compound having from 4 to 35 carbon atoms (B12) includes, for example, monofunctional to hexafunctional (meth)acrylates described below.

The monofunctional (meth)acrylate includes, for example, ethyl (meth)acrylate, hexyl (meth)acrylate, 2-ethylhexyl (meth)acrylate, tert-octyl (meth)acrylate, isoamyl (meth)acrylate, decyl (meth)acrylate, isodecyl (meth)acrylate, stearyl (meth)acrylate, isostearyl (meth)acrylate, cyclohexyl (meth)acrylate, 4-n-butylcyclohexyl (meth)acrylate, bornyl (meth)acrylate, isobornyl (meth)acrylate, benzyl (meth)acrylate, 2-ethylhexyl diglycol (meth)acrylate, butoxyethyl (meth)acrylate, 2-chloroethyl (meth)acrylate, 4-bromobutyl (meth)acrylate, cyanoethyl (meth)acrylate, benzyl (meth)acrylate, butoxymethyl (meth)acrylate, methoxypropylene mono(meth)acrylate, 3-methoxybutyl (meth)acrylate, alkoxymethyl (meth)acrylates, 2-ethylhexylcarbitol (meth)acrylate, alkoxyethyl (meth)acrylates, 2-(2-methoxyethoxy)ethyl (meth)acrylate, 2-(2-butoxyethoxy)ethyl (meth)acrylate, 2,2,2-tetrafluoroethyl (meth)acrylate, 1H,1H,2H,2H-perfluorodecyl (meth)acrylate, 4-butylphenyl (meth)acrylate, phenyl (meth)acrylate, 2,4,5-tetramethylphenyl (meth)acrylate, 4-chlorophenyl (meth)acrylate, phenoxymethyl (meth)acrylate, phenoxyethyl (meth)acrylate, glycidyl (meth)acrylate, glycidyloxybutyl (meth)acrylate, glycidyloxyethyl (meth)acrylate, glycidyloxypropyl (meth)acrylate, diethyleneglycol monovinyl ether mono(meth)acrylate, tetrahydrofurfuryl (meth)acrylate, hydroxyalkyl (meth)acrylates, 2-hydroxyethyl (meth)acrylate, 3-hydroxypropyl (meth)acrylate, 2-hydroxypropyl (meth)acrylate, 2-hydroxybutyl (meth)acrylate, 4-hydroxybutyl (meth)acrylate, dimethylaminoethyl (meth)acrylate, diethylaminoethyl (meth)acrylate, dimethylaminopropyl (meth)acrylate, diethylaminopropyl(meth)acrylate, trimethoxysilylpropyl (meth)acrylate, trimethoxysilylpropyl (meth)acrylate, trimethylsilypropyl (meth)acrylate, polyethylene oxide monomethyl ether (meth)acrylate, oligoethylene oxide monomethyl ether (meth)acrylate, polyethylene oxide (meth)acrylate, oligoethylene oxide (meth)acrylate, oligoethylene oxide monoalkyl ether (meth)acrylate, polyethylene oxide monoalkyl ether (meth)acrylate, dipropylene glycol (meth)acrylate, polypropylene oxide monoalkyl ether (meth)acrylate, oligopropylene oxide monoalkyl ether (meth)acrylate, 2-methacryloyloxyethylsuccinic acid, 2-methacryloyloxyhexahydrophthalic acid, 2-methacryloyloxyethyl-2-hydroxypropyl phthalate, butoxydiethylene glycol (meth)acrylate, trifluoroethyl (meth)acrylate, perfluorooctylethyl (meth)acrylate, 2-hydroxy-3-phenoxypropyl (meth)acrylate, EO-modified phenol (meth)acrylate, EO-modified cresol (meth)acrylate, EO-modified nonylphenol (meth)acrylate, PO-modified nonylphenol (meth)acrylate and EO-modified 2-ethylhexyl (meth)acrylate. In the above and hereinafter, EO denotes ethylene oxide and PO denotes propylene oxide.

The difunctional (meth)acrylate includes, for example, 1,4-butane di(meth)acrylate, 1,6-hexane di(meth)acrylate, polypropylene di(meth)acrylate, 1,6-hexanediol di(meth)acrylate, 1,10-decanediol di(meth)acrylate, neopentyl di(meth)acrylate, neopentyl glycol di(meth)acrylate, 2,4-dimethyl-1,5-pentanediol di(meth)acrylate, butylethylpropanediol di(meth)acrylate, ethoxylated cyclohexane methanol di(meth)acrylate, polyethylene glycol di(meth)acrylate, oligoethylene glycol di(meth)acrylate, ethylene glycol di(meth)acrylate, 2-ethyl-2-butylbutanediol di(meth)acrylate, neopentyl glycol hydroxypivalate di(meth)acrylate, EO-modified bisphenol A di(meth)acrylate, bisphenol F polyethoxy di(meth)acrylate, polypropylene glycol di(meth)acrylate, oligopropylene glycol di(meth)acrylate, 1,4-butanediol di(meth)acrylate, 2-ethyl-2-butylpropanediol di(meth)acrylate, 1,9-nonane di(meth)acrylate, propoxylated ethoxylated bisphenol A di(meth)acrylate and tricyclodecane di(meth)acrylate.

The trifunctional (meth)acrylate includes, for example, trimethylolpropane tri(meth)acrylate, trimethylolethane tri(meth)acrylate, alkyleneoxide-modified trimethylolpropane tri(meth)acrylate, pentaerythritol tri(meth)acrylate, dipentaerythritol tri(meth)acrylate, trimethylolpropane tri((meth)acryloyloxypropyl)ether, isocyanuric acid alkylene oxide-modified tri(meth)acrylate, dipentaerythritol propionate tri(meth)acrylate, tri((meth)acryloyloxyethyl)isocyanurate, hydroxypivalaldehyde-modified dimethylolpropane tri(meth)acrylate, sorbitol tri(meth)acrylate, plopoxylated trimethylolpropane tri(meth)acrylate and ethoxylated glycerol tri(meth)acrylate.

The tetrafunctional (meth)acrylate includes, for example, urethane tetra(meth)acrylate, pentaerythritol tetra(meth)acrylate, sorbitol tetra(meth)acrylate, ditrimethylolpropane tetra(meth)acrylate, dipentaerythritol propionate tetra(meth)acrylate and ethoxylated pentaerythritol tetra(meth)acrylate.

The pentafunctional (meth)acrylate includes, for example, sorbitol penta(meth)acrylate and dipentaerythritol penta(meth)acrylate.

The hexafunctional (meth)acrylate includes, for example, dipentaerythritol hexa(meth)acrylate, sorbitol hexa(meth)acrylate, alkylene oxide-modified phosphazene hexa(meth)acrylate and caprolactone-modified dipentaerythritol hexa(meth)acrylate.

The aromatic vinyl compound having from 6 to 35 carbon atoms (B13) includes, for example, vinyl thiophene, vinyl furan, vinyl pyridine, styrene, methyl styrene, trimethylstyrene, ethylstyrene, isopropylstyrene, chloromethylstyrene, methoxystyrene, acetoxystyrene, chlorostyrene, dichlorostyrene, bromostyrene, methyl vinyl benzoate, 3-methylstyrene, 4-methylstyrene, 3-ethylstyrene, 4-ethylstyrene, 3-propylstyrene, 4-propylstyrene, 3-butylstyrene, 4-butylstyrene, 3-hexylstyrene, 4-hexylstyrene, 3-octylstyrene, 4-octylstyrene, 3-(2-ethylhexyl)styrene, 4-(2-ethylhexyl)styrene, allylstyrene, isopropenylstyrene, butenylstyrene, octenylstyrene, 4-tert-butoxycarbonylstyrene, 4-methoxystyrene, and 4-tert-butoxystyrene.

The vinyl ether compound having from 3 to 35 carbon atoms (B14) includes, for example, monofunctional and multifunctional vinyl ethers described below.

The monofunctional vinyl ether includes, for example, methyl vinyl ether, ethyl vinyl ether, propyl vinyl ether, n-butyl vinyl ether, tert-butyl vinyl ether, 2-ethyl hexyl vinyl ether, n-nonyl vinyl ether, lauryl vinyl ether, cyclohexyl vinyl ether, cyclohexylmethyl vinyl ether, 4-methylcyclohexylmethyl vinyl ether, benzyl vinyl ether, dicyclopentenyl vinyl ether, 2-dicyclopentenoxyethyl vinyl ether, methoxyethyl vinyl ether, ethoxyethyl vinyl ether, butoxyethyl vinyl ether, methoxyethoxy ethyl vinyl ether, ethoxyethoxy ethyl vinyl ether, methoxy polyethylene glycol vinyl ether, tetrahydrofurfuryl vinyl ether, 2-hydroxyethyl vinyl ether, 2-hydroxypropyl vinyl ether, 4-hydroxybutyl vinyl ether, 4-hydroxymethylcyclohexylmethyl vinyl ether, diethylene glycol monovinyl ether, polyethylene glycol vinyl ether, chloroethyl vinyl ether, chlorobutyl vinyl ether, chloroethoxyethyl vinyl ether, phenylethyl vinyl ether and phenoxypolyethylene glycol vinyl ether.

The multifunctional vinyl ether includes, for example, a divinyl ether, for example, ethylene glycol divinyl ether, diethylene glycol divinyl ether, polyethylene glycol divinyl ether, propylene glycol divinyl ether, butylene glycol divinyl ether, hexanediol divinyl ether, bisphenol A alkylene oxide divinyl ether or bisphenol F alkylene oxide divinyl ether; trimethylolethane trivinyl ether, trimethylolpropane trivinyl ether, ditrimethylolpropane tetravinyl ether, glycerol trivinyl ether, pentaerythritol tetravinyl ether, dipentaerythritol pentavinyl ether, dipentaerythritol hexavinyl ether, ethylene oxide adduct of trimethylolpropane trivinyl ether, propylene oxide adduct of trimethylolpropane trivinyl ether, ethylene oxide of ditrimethylolpropane tetravinyl ether, propylene oxide adduct of ditrimethylolpropane tetravinyl ether, ethylene oxide adduct of pentaerythritol tetravinyl ether, propylene oxide adduct of pentaerythritol tetravinyl ether, ethylene oxide adduct of dipentaerythritol hexavinyl ether and propylene oxide adduct of dipentaerythritol hexavinyl ether.

The other radical polymerizable compound (B15) includes, for example, a vinyl ester compound (for example, vinyl acetate, vinyl propionate or vinyl versatate), an allyl ester compound (for example, allyl acetate), a halogen-containing monomer (for example, vinylidene chloride or vinyl chloride) and an olefin compound (for example, ethylene or propylene).

Of the radical polymerizable compounds, from the standpoint of curing speed, the (meth)acrylamide compound (B11) and the (meth)acrylate compound (B12) are preferred, and the (meth)acrylate compound (B12) is particularly preferred.

The ionic polymerizable compound (B2) includes, for example, an epoxy compound having from 3 to 20 carbon atoms (B21) and an oxetane compound having from 4 to 20 carbon atoms (B22).

The epoxy compound having from 3 to 20 carbon atoms (B21) includes, for example, monofunctional and multifunctional epoxy compounds described below.

The monofunctional epoxy compound includes, for example, phenyl glycidyl ether, p-tert-butylphenyl glycidyl ether, butyl glycidyl ether, 2-ethylhexyl glycidyl ether, allyl glycidyl ether, 1,2-butylene oxide, 1,3-butadiene monoxide, 1,2 epoxydodecane, epichlorohydrin, 1,2-epoxydecane, styrene oxide, cyclohexene oxide, 3-methacryloyloxymethylcyclohexene oxide, 3-acryloyloxymethylcyclohexene oxide and 3-vinylcyclohexene oxide.

The multifunctional epoxy compound includes, for example, 2,2-bis(4-glycidyloxyphenyl)propane, bisphenol A diglycidyl ether, bisphenol F diglycidyl ether, bisphenol S diglycidyl ether, brominated bisphenol A diglycidyl ether, brominated bisphenol F diglycidyl ether, brominated bisphenol S diglycidyl ether, epoxy novolac resin, hydrogenated bisphenol A diglycidyl ether, hydrogenated bisphenol F diglycidyl ether, hydrogenated bisphenol S diglycidyl ether, 3,4-epoxycyclohexylmethyl-3′,4′-epoxycyclohexanecarboxylate, 2-(3,4-epoxycyclohexyl-5,5-spiro-3,4-epoxy)cyclohexane meta-dioxane, bis(3,4-epoxycyclohexylmethyl)adipate, vinylcyclohexene oxide, 4-vinyl epoxycyclohexane, bis(3,4-epoxy-6-methylcyclohexylmethyl)adipate, 3,4-epoxy-6-methylcyclohexyl-3′,4′-epoxy-6′-methylcyclohexane carboxylate, methylenebis (3,4-epoxycyclohexane), dicyclopentadiene diepoxide, ethylene glycol di(3,4-epoxycyclohexylmethyl)ether, ethylene bis(3,4-epoxycyclohexane carboxylate), dioctyl epoxy hexahydrophthalate, di-2-ethylhexyl epoxyhexahydrophthalate, 1,4-butanediol diglycidyl ether, 1,6-hexanediol diglycidyl ether, glycerol triglycidyl ether, trimethylolpropane triglycidyl ether, polyethylene glycol diglycidyl ether, polypropylene glycol diglycidyl ether, 1,1,3-tetradecadiene dioxide, limonene dioxide, 1,2,7,8-diepoxyoctane and 1,2,5,6-diepoxycyclooctane.

Of the epoxy compounds, from the standpoint of excellent curing speed, an aromatic epoxide and an alicyclic epoxide are preferred, and the alicyclic epoxide is particularly preferred.

The oxetane compound having from 4 to 20 carbon atoms (B22) includes, for example, compounds having from 1 to 6 oxetane rings.

The compound having 1 oxetane ring includes, for example, 3-ethyl-3-hydroxymethyl oxetane, 3-(meth)allyloxymethyl-3-ethyl oxetane, (3-ethyl-3-oxetanylmethoxy)methylbenzene, 4-fluoro-[1-(3-ethyl-3-oxetanylmethoxy)methyl]benzene, 4-methoxy[1-(3-ethyl-3-oxetanylmethoxy)methyl]benzene, [1-(3-ethyl-3-oxetanylmethoxy)ethyl]phenyl ether, isobutoxymethyl(3-ethyl-3-oxetanylmethyl)ether, isobornyloxyethyl(3-ethyl-3-oxetanylmethyl)ether, isobornyl(3-ethyl-3-oxetanylmethyl)ether, 2-ethylhexyl(3-ethyl-3-oxetanylmethyl)ether, ethyldiethylene glycol(3-ethyl-3-oxetanylmethyl)ether, dicyclopentadiene(3-ethyl-3-oxetanylmethyl)ether, dicyclopentenyloxyethyl(3-ethyl-3-oxetanylmethyl)ether, dicyclopentenyl(3-ethyl-3-oxetanylmethyl)ether, tetrahydrofurfuryl(3-ethyl-3-oxetanylmethyl)ether, tetrabromophenyl(3-ethyl-3-oxetanylmethyl)ether, 2-tetrabromophenoxyethyl(3-ethyl-3-oxetanylmethyl)ether, tribromophenyl(3-ethyl-3-oxetanylmethyl)ether, 2-tribromophenoxyethyl(3-ethyl-3-oxetanylmethyl)ether, 2-hydroxyethyl(3-ethyl-3-oxetanylmethyl)ether, 2-hydroxypropyl(3-ethyl-3-oxetanylmethyl)ether, butoxyethyl(3-ethyl-3-oxetanylmethyl)ether, pentachlorophenyl(3-ethyl-3-oxetanylmethyl)ether, pentabromophenyl(3-ethyl-3-oxetanylmethyl)ether and bornyl(3-ethyl-3-oxetanylmethyl)ether.

The compound having from 2 to 6 oxetane rings includes, for example, 3,7-bis(3-oxetanyl)-5-oxanonane, 3,3′-(1,3-(2-methylenyl)propanediylbis(oxymethylene))bis(3-ethyloxetane), 1,4-bis[(3-ethyl-3-oxetanylmethoxy)methyl]benzene, 1,2-bis[(3-ethyl-3-oxetanylmethoxy)methyl]ethane, 1,3-bis[(3-ethyl-3-oxetanylmethoxy)methyl]propane, ethylene glycol bis(3-ethyl-3-oxetanylmethyl)ether, dicyclopentenyl bis(3-ethyl-3-oxetanylmethyl)ether, triethylene glycol bis(3-ethyl-3-oxetanylmethyl)ether, tetraethylene glycol bis(3-ethyl-3-oxetanylmethyl)ether, tricyclodecanediyldimethylene (3-ethyl-3-oxetanylmethyl)ether, trimethylol propane tris(3-ethyl-3-oxetanylmethyl)ether, 1,4-bis(3-ethyl-3-oxetanylmethoxy)butane, 1,6-bis(3-ethyl-3-oxetanylmethoxy)hexane, pentaerythritol tris(3-ethyl-3-oxetanylmethyl)ether, pentaerythritol tetrakis(3-ethyl-3-oxetanylmethyl)ether, polyethylene glycol bis(3-ethyl-3-oxetanylmethyl)ether, dipentaerythritol hexakis(3-ethyl-3-oxetanylmethyl)ether, dipentaerythritol pentakis(3-ethyl-3-oxetanylmethyl)ether, dipentaerythritol tetrakis(3-ethyl-3-oxetanylmethyl)ether, caprolactone-modified dipentaerythritol hexakis(3-ethyl-3-oxetanylmethyl)ether, caprolactone-modified dipentaerythritol pentakis(3-ethyl-3-oxetanylmethyl)ether, ditrimethylolpropane tetrakis(3-ethyl-3-oxetanylmethyl)ether, EO-modified bisphenol A bis(3-ethyl-3-oxetanylmethyl)ether, PO-modified bisphenol A bis(3-ethyl-3-oxetanylmethyl)ether, EO-modified hydrogenated bisphenol A bis(3-ethyl-3-oxetanylmethyl)ether, PO-modified hydrogenated bisphenol A bis(3-ethyl-3-oxetanylmethyl)ether and EO-modified bisphenol F (3-ethyl-3-oxetanylmethyl)ether.

A polyhydric alcohol, for example, glycerol is also preferably used as the diluent.

Of the diluents, from the standpoint of adhesion property and releasing property, the radical polymerizable compound is preferably used, and the radical polymerizable compound having a urethane bond is most preferably used.

The content of the diluent (B) is preferably from 5 to 75% by weight, more preferably from 10 to 70% by weight, still more preferably from 10 to 60% by weight, based on the total solid content of the temporary adhesive from the standpoint of good adhesion strength and good releasing property.

Also, a ratio (weight ratio) of contents of the diluent (B) and the polymer compound (A) is preferably from 90/10 to 10/90, and more preferably from 20/80 to 80/20.

### (C) Solvent

The temporary adhesive according to the invention contains a solvent (ordinarily an organic solvent). The solvent is basically not particularly limited as long as it satisfies solubility of each of the components and coating property of the temporary adhesive.

The organic solvent preferably includes, an ester, for example, ethyl acetate, n-butyl acetate, isobutyl acetate, amyl formate, isoamyl acetate, isobutyl acetate, butyl propionate, isopropyl butyrate, ethyl butyrate, butyl butyrate, methyl lactate, ethyl lactate, an alkyl oxyacetate (for example, methyl oxyacetate, ethyl oxyacetate, butyl oxyacetate, methyl methoxyacetate, ethyl methoxyacetate, butyl methoxyacetate, methyl ethoxyacetate or ethyl ethoxyacetate), an alkyl 3-oxypropionate (for example, methyl 3-oxypropionate, ethyl 3-oxypropionate, methyl 3-methoxypropionate, ethyl 3-methoxypropionate, methyl 3-ethoxypropionate or ethyl 3-ethoxypropionate), an alkyl 2-oxypropionate (for example, methyl 2-oxypropionate, ethyl 2-oxypropionate, propyl 2-oxypropionate, methyl 2-methoxypropionate, ethyl 2-methoxypropionate, propyl 2-methoxypropionate, methyl 2-ethoxypropionate or ethyl 2-ethoxypropionate), methyl 2-oxy-2-methylpropionate, ethyl 2-oxy-2-methylpropionate, methyl 2-ethoxy-2-methylpropionate, ethyl 2-methoxy-2-methylpropionate, methyl pyruvate, ethyl pyruvate, propyl pyruvate, methyl acetoacetate, ethyl acetoacetate, methyl 2-oxobutanoate or ethyl 2-oxobutanoate; an ether, for example, diethylene glycol dimethyl ether, tetrahydrofuran, ethylene glycol monomethyl ether, ethylene glycol monoethyl ether, methyl cellosolve acetate, ethyl cellosolve acetate, diethylene glycol monomethyl ether, diethylene glycol monoethyl ether, diethylene glycol monobutyl ether, propylene glycol monomethyl ether, 1-methoxy-2-propanol acetate, propylene glycol monoethyl ether acetate or propylene glycol monopropyl ether acetate; a ketone, for example, 2-butanone, cyclohexanone, 2-heptanone or 3-heptanone; and an aromatic hydrocarbon, for example, toluene or xylene.

From the standpoint of improving the coated surface state and the like, the solvents are also preferably used in the state of mixing two or more thereof. In this case, a mixed solution composed of two or more solvents selected from methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, ethyl carbitol acetate, butyl carbitol acetate, propylene glycol methyl ether and propylene glycol methyl ether acetate is particularly preferred.

The content of the solvent in the temporary adhesive is set such that the total solid content concentration of the temporary adhesive becomes preferably from 5 to 80% by weight, more preferably from 5 to 70% by weight, particularly preferably from 10 to 60% by weight, from the standpoint of coating property.

(D) Compound which Generates Radical or Acid by Irradiation of Active Light or Radiation

The temporary adhesive according to the invention preferably further contains a compound which generates a radical or an acid by irradiation of active light or radiation (D).

As the compound which generates a radical or an acid by irradiation of active light or radiation (D), for example, compounds known as polymerization initiators described below can be used.

The polymerization initiator is not particularly limited as long as it has an ability to initiate a polymerization reaction (crosslinking reaction) of a polymer compound having a crosslinkable group as the polymer compound (A) or a reactive compound having a crosslinkable group as the diluent (B), and can be appropriately selected from known polymerization initiators. For example, a polymerization initiator having photosensitivity to light from an ultraviolet ray region to a visible region is preferred. Also, the polymerization initiator may be an activator which causes any action with a photo-excited sensitizer to produce an active radical or may be an initiator which generates an acid to initiate a cationic polymerization according to the kind of the monomer.

Further, it is preferred that the polymerization initiator contains at least one compound having a molecular absorption coefficient of at least about 50 within the range from about 300 to 800 nm (preferably from 330 to 500 nm).

As the polymerization initiator, known compounds are used without limitation. The polymerization initiator includes, for example, a halogenated hydrocarbon derivative (for example, a compound having a triazine skeleton, a compound having an oxadiazole skeleton or a compound having a trihalomethyl group), an acylphosphine compound, for example, an acylphosphine oxide, a hexaarylbiimidazole, an oxime compound, for example, an oxime derivative, an organic peroxide, a thio compound, a ketone compound, an aromatic onium salt, a ketoxime ether, an aminoacetophenone compound, a hydroxyacetophenone, an azo compound, an azide compound, a metallocene compound, an organic boron compound, and an iron arene compound.

The halogenated hydrocarbon compound having a triazine skeleton includes, for example, compounds described in Wakabayashi et al., Bull. Chem. Soc. Japan, 42, 2924 (1969), compounds described in British Patent 1,388,492, compounds described in JP-A-53-133428, compounds described in German Patent 3,337,024, compounds described in F. C. Schaefer et al., J. Org. Chem., 29, 1527 (1964), compounds described in JP-A-62-58241, compounds described in JP-A-5-281728, compounds described in JP-A-5-34920, and compounds described in U.S. Pat. No. 4,212,976.

The compounds described in U.S. Pat. No. 4,212,976 include, for example, a compound having an oxadiazole skeleton (for example, 2-trichloromethyl-5-phenyl-1,3,4-oxadiazole, 2-trichloromethyl-5-(4-chlorophenyl)-1,3,4-oxadiazole, 2-trichloromethyl-5-(1-naphthyl)-1,3,4-oxadiazole, 2-trichloromethyl-5-(2-naphthyl)-1,3,4-oxadiazole, 2-tribromomethyl-5-phenyl-1,3,4-oxadiazole, 2-tribromomethyl-5-(2-naphthyl)-1,3,4-oxadiazole, 2-trichloromethyl-5-styryl-1,3,4-oxadiazole, 2-trichloromethyl-5-(4-chlorostyryl)-1,3,4-oxadiazole, 2-trichloromethyl-5-(4-methoxystyryl)-1,3,4-oxadiazole, 2-trichloromethyl-5-(1-naphthyl)-1,3,4-oxadiazole, 2-trichloromethyl-5-(4-n-buthoxystyryl)-1,3,4-oxadiazole or 2-tribromomethyl-5-styryl-1,3,4-oxadiazole).

Also, examples of the polymerization initiator other than the polymerization initiators described above include an acridine derivative (for example, 9-phenylacridine or 1,7-bis(9,9′-acridinyl)heptane), N-phenylglycine, a polyhalogen compound (for example, carbon tetrabromide, phenyl tribromomethyl sulfone or phenyl trichloromethyl ketone), a coumarin (for example, 3-(2-benzofuranoyl)-7-diethylaminocoumarin, 3-(2-benzofuroyl)-7-(1-pyrrolidinyl)coumarin, 3-benzoyl-7-diethylaminocoumarin, 3-(2-methoxybenzoyl)-7-diethylaminocoumarin, 3-(4-dimethylaminobenzoyl)-7-diethylaminocoumarin, 3,3′-carbonylbis(5,7-di-n-propoxycoumarin), 3,3′-carbonylbis(7-diethylaminocoumarin), 3-benzoyl-7-methoxycoumarin, 3-(2-furoyl)-7-diethylaminocoumarin, 3-(4-diethylaminocinnamoyl)-7-diethylaminocoumarin, 7-methoxy-3-(3-pyridylcarbonyl)coumarin, 3-benzoyl-5,7-dipropoxycoumarin, 7-benzotriazol-2-ylcoumarin, coumarin compounds described, for example, in JP-A-5-19475, JP-A-7-271028, JP-A-2002-363206, JP-A-2002-363207, JP-A-2002-363208 and JP-A-2002-363209), an acylphosphine oxide (for example, bis(2,4,6-trimethylbenzoyl)-phenylphosphine oxide, bis(2,6-dimethoxybenzoyl)-2,4,4-trimethylpentylphenylphosphine oxide or LUCIRIN TPO), a metallocene (for example, bis (η5-2,4-cyclopentadien-1-yl)-bis(2,6-difluoro-3-(1H-pyrrol-1-yl)-phenyl)titanium or η5-cyclopentadienyl-η6-cumenyl-iron(1+)-hexafluorophosphate(1−)), compounds described in JP-A-53-133428, JP-B-57-1819 (the term “JP-B” as used herein means an “examined Japanese patent publication”), JP-B-57-6096 and U.S. Pat. No. 3,615,455.

The ketone compound includes, for example, benzophenone, 2-methylbenzophenone, 3-methylbenzophenone, 4-methylbenzophenone, 4-methoxybenzophenone, 2-chlorobenzophenone, 4-chlorobenzophenone, 4-bromobenzophenone, 2-carboxybenzophenone, 2-ethoxycarbonylbenzophenone, benzophenone tetracarboxylic acid or tetramethyl ester thereof, a 4,4′-bis(dialkylamino)benzophenone (for example, 4,4′-bis(dimethylamino)benzophenone, 4,4′-bis(dicyclohexylamino)benzophenone, 4,4′-bis(diethylamino)benzophenone or 4,4′-bis(dihydroxyethylamino)benzophenone), 4-methoxy-4′-dimethylaminobenzophenone, 4,4′-dimethoxybenzophenone, 4-dimethylaminobenzophenone, 4-dimethylaminoacetophenone, benzyl, anthraquinone, 2-tert-butylanthraquinone, 2-methylanthraquinone, phenanthraquinone, xanthone, thioxanthone, 2-chlorothioxanthone, 2,4-diethylthioxanthone, fluorenone, 2-benzyldimethylamino-1-(4-morpholinophenyl)-1-butanone, 2-methyl-1-[4-(methylthio)phenyl]-2-morpholino-1-propanone, 2-hydroxy-2-methyl-[4-(1-methylvinyl)phenyl]propanol oligomer, benzoin, a benzoin ether (for example, benzoin methyl ether, benzoin ethyl ether, benzoin propyl ether, benzoin isopropyl ether, benzoin phenyl ether or benzyl dimethyl ketal), acridone, chloroacridone, N-methylacridone, N-butylacridone and N-butylchloroacridone.

As the polymerization initiator, a hydroxyacetophenone compound, an aminoacetophenone compound and an acylphosphine compound can also be preferably used. More specifically, for example, an aminoacetophenone initiator described in JP-A-10-291969 and an acylphosphine oxide initiator described in Japanese Patent No. 4225898 can also be used.

As the hydroxyacetophenone initiator, IRGACURE-184, DAROCUR-1173, IRGACURE-500, IRGACURE-2959 and IRGACURE-127 (trade names, produced by BASF Corp.) can be used. As the aminoacetophenone initiator, commercially available products IRGACURE-907, IRGACURE-369 and IRGACURE-379 (trade names, produced by BASF Corp.) can be used. As the aminoacetophenone initiator, compounds described in JP-A-2009-191179, where the absorption wavelength matches the light source having a long wavelength, for example, 365 nm or 405 nm, can also be used. Also, as the acylphosphine initiator, commercially available products IRGACURE-819 and DAROCUR-TPO (trade names, produced by BASF Corp.) can be used.

The polymerization initiator more preferably includes an oxime compound. As specific examples of the oxime initiator, compounds described in JP-A-2001-233842, compounds describe in JP-A-2000-80068 and compounds described in JP-A-2006-342166 can be used.

Examples of the oxime compound, for example, an oxime derivative, which is preferably used as the polymerization initiator in the invention, include 3-benzoyloxyiminobutan-2-one, 3-acetoxyiminobutan-2-one, 3-propionyloxyiminobutan-2-one, 2-acetoxyiminopentan-3-one, 2-acetoxyimino-1-phenylpropan-1-one, 2-benzoyloxyimino-1-phenylpropan-1-one, 3-(4-toluenesulfonyloxy)iminobutan-2-one and 2-ethoxycarbonyloxyimino-1-phenylpropan-1-one.

The oxime ester compound includes, for example, compounds described in J.C.S. Perkin II, (1979) pp. 1653-1660, J.C.S. Perkin II, (1979) pp. 156-162, Journal of Photopolymer Science and Technology, (1995) pp 202-232, JP-A-2000-66385, JP-A-2000-80068, JP-T-2004-534797 and JP-A-2006-342166.

As the commercially available product, IRGACURE-OXE01 (produced by BASF Corp.) and IRGACURE-OXE02 (manufactured by BASF Corp.) are also preferably used.

In addition, as the oxime ester compound other than the oxime ester compounds described above, compounds described in JP-T-2009-519904, wherein oxime is connected to the N-position of carbazole, compounds described in U.S. Pat. No. 7,626,957, wherein a hetero-substituent is introduced into the benzophenone moiety, compounds described in JP-A-2010-15025 and U.S. Patent Publication No. 2009/0292039, wherein a nitro group is introduced into the dye moiety, ketoxime compounds described in WO 2009/131189, compounds containing a triazine skeleton and an oxime skeleton within the same molecule described in U.S. Pat. No. 7,556,910, and compounds having an absorption maximum at 405 nm and exhibiting good sensitivity for a g-line light source described in JP-A-2009-221114 may also be used.

Furthermore, cyclic oxime compounds described in JP-A-2007-231000 and JP-A-2007-322744 can also be preferably used. Of the cyclic oxime compounds, cyclic oxime compounds condensed to a carbazole dye described in JP-A-2010-32985 and JP-A-2010-185072 have high light absorptivity and thus are preferred from the standpoint of high sensitivity.

Further, compounds described in JP-A-2009-242469 having an unsaturated bond at a specific site of an oxime compound can achieve high sensitivity by regenerating an active radical from a polymerization inactive radical, and thus are preferably used.

Oxime compounds having a specific substituent described in JP-A-2007-269779 and oxime compounds having a thioaryl group described in JP-A-2009-191061 are most preferred.

Specifically, the oxime polymerization initiator is preferably a compound represented by formula (OX-1) shown below. The oxime compound may be an oxime compound of (E) form wherein the N—O bond of the oxime is (E) form, an oxime compound of (Z) form wherein the N—O bond of the oxime is (Z) form, or a mixture of the (E) form and the (Z) form.

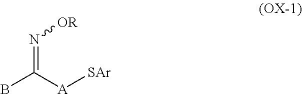

In formula (OX-1), R and B each independently represents a monovalent substituent, A represents a divalent organic group, and Ar represents an aryl group.

In formula (OX-1), the monovalent substituent represented by R is preferably a monovalent nonmetallic atomic group.

Examples of the monovalent nonmetallic atomic group include an alkyl group, an aryl group, an acyl group, an alkoxycarbonyl group, an aryloxycarbonyl group, a heterocyclic group, an alkylthiocarbonyl group and an arylthiocarbonyl group. Also, these groups may have one or more substituents. Further, the substituent described above may be substituted with other substituent(s).

Examples of the substituent include a halogen atom, an aryloxy group, an alkoxycarbonyl group, an aryloxycarbonyl group, an acyloxy group, an acyl group, an alkyl group and an aryl group.

The alkyl group which may have a substituent is preferably an alkyl group having from 1 to 30 carbon atoms, and specific examples thereof include a methyl group, an ethyl group, a propyl group, a butyl group, a hexyl group, an octyl group, a decyl group, a dodecyl group, an octadecyl group, an isopropyl group, an isobutyl group, a sec-butyl group, a tert-butyl group, a 1-ethylpentyl group, a cyclopentyl group, a cyclohexyl group, a trifluoromethyl group, a 2-ethylhexyl group, a phenacyl group, a 1-naphthoylmethyl group, a 2-naphthoylmethyl group, a 4-methylsulfanylphenacyl group, a 4-phenylsulfanylphenacyl group, a 4-dimethylaminophenacyl group, a 4-cyanophenacyl group, a 4-methylphenacyl group, a 2-methylphenacyl group, a 3-fluorophenacyl group, a 3-trifluoromethylphenacyl group and a 3-nitrophenacyl group.

The aryl group which may have a substituent is preferably an aryl group having from 6 to 30 carbon atoms, and specific examples thereof include a phenyl group, a biphenyl group, a 1-naphthyl group, a 2-naphthyl group, a 9-anthryl group, a 9-phenanthryl group, a 1-pyrenyl group, a 5-naphthacenyl group, a 1-indenyl group, a 2-azulenyl group, a 9-fluorenyl group, a terphenyl group, a quarter phenyl group, an o-tolyl group, a m-tolyl group, p-tolyl group, a xylyl group, an o-cumenyl group, a m-cumenyl group, a p-cumenyl group, a mesityl group, a pentalenyl group, a binaphthalenyl group, a temaphthalenyl group, a quarter naththalenyl group, a heptalenyl group, a biphenylenyl group, an indacenyl group, a fluoranthenyl group, an acenaphthylenyl group, an aceanthrylenyl group, a phenalenyl group, a fluorenyl group, an anthryl group, a bianthracenyl group, a teranthracenyl group, a quarter anthracenyl group, an anthraquinolyl group, a phenanthryl group, a triphenylenyl group, a pyrenyl group, a chrysenyl group, a naphthacenyl group, a pleiadenyl group, a picenyl group, a perylenyl group, a pentaphenyl group, a pentacenyl group, a tetraphenylenyl group, a hexaphenyl group, a hexacenyl group, a rubicenyl group, a coronenyl group, a trinaphthylenyl group, a heptaphenyl group, a heptacenyl group, a pyranthrenyl group and an ovalenyl group.

The acyl group which may have a substituent is preferably an acyl group having from 2 to 20 carbon atoms, and specific examples thereof include an acetyl group, a propanoyl group, a butanoyl group, a trifluoroacetyl group, a pentanoyl group, a benzoyl group, a 1-naphthoyl group, a 2-naphthoyl group, a 4-methylsulfanylbenzoyl group, a 4-phenylsulfanylbenzoyl group, a 4-dimethylaminobenzoyl group, a 4-diethylaminobenzoyl group, a 2-chlorobenzoyl group, a 2-methylbenzoyl group, a 2-methoxybenzoyl group, a 2-butoxybenzoyl group, a 3-chlorobenzoyl group, a 3-trifluoromethylbenzoyl group, a 3-cyanobenzoyl group, a 3-nitrobenzoyl group, a 4-fluorobenzoyl group, a 4-cyanobenzoyl group and a 4-methoxybenzoyl group.

The alkoxycarbonyl group which may have a substituent is preferably an alkoxycarbonyl group having from 2 to 20 carbon atoms, and specific examples thereof include a methoxycarbonyl group, an ethoxycarbonyl group, a propoxycarbonyl group, a butoxycarbonyl group, a hexyloxycarbonyl group, an octyloxycarbonyl group, a decyloxycarbonyl group, an octadecyloxycarbonyl group and a trifluoromethyloxycarbonyl group.

Specific examples of the aryloxycarbonyl group which may have a substituent include a phenoxycarbonyl group, a 1-naphthyloxycarbonyl group, a 2-naphthyloxycarbonyl group, a 4-methylsulfanylphenyloxycarbonyl group, a 4-phenylsulfanylphenyloxycarbonyl group, a 4-dimethylaminophenyloxycarbonyl group, a 4-diethylaminophenyloxycarbonyl group, a 2-chlorophenyloxycarbonyl group, a 2-methylphenyloxycarbonyl group, a 2-methoxyphenyloxycarbonyl group, a 2-butoxyphenyloxycarbonyl group, a 3-chlorophenyloxycarbonyl group, a 3-trifluoromethylphenyloxycarbonyl group, a 3-cyanophenyloxycarbonyl group, a 3-nitrophenyloxycarbonyl group, a 4-fluorophenyloxycarbonyl group, a 4-cyanophenyloxycarbonyl group and a 4-methoxyphenyloxycarbonyl group.

The heterocyclic group which may have a substituent is preferably an aromatic or aliphatic heterocyclic group containing a nitrogen atom, an oxygen atom, a sulfur atom or a phosphorus atom.

Specific examples thereof include a thienyl group, a benzo[b]thienyl group, a naphtho[2,3-b]thienyl group, a thianthrenyl group, a furyl group, a pyranyl group, an isobenzofuranyl group, a chromenyl group, a xanthenyl group, a phenoxathiinyl group, a 2H-pyrrolyl group, a pyrrolyl group, an imidazolyl group, a pyrazolyl group, a pyridyl group, a pyrazinyl group, a pyrimidinyl group, a pyridazinyl group, an indolizinyl group, an isoindolyl group, a 3H-indolyl group, an indolyl group, a 1H-indazolyl group, a purinyl group, a 4H-quinolizinyl group, an isoquinolyl group, a quinolyl group, a phthalazinyl group, a naphthyridinyl group, a quinoxalinyl group, a quinazolinyl group, a cinnolinyl group, a pteridinyl group, a 4aH-carbazolyl group, a carbazolyl group, a β-carbolinyl group, a phenanthridinyl group, an acridinyl group, a perimidinyl group, a phenanthrolinyl group, a phenazinyl group, a phenarsazinyl group, an isothiazolyl group, a phenothiazinyl group, an isoxazolyl group, a furazanyl group, a phenoxazinyl group, an isochromanyl group, a chromanyl group, a pyrrolidinyl group, a pyrrolinyl group, an imidazolidinyl group, an imidazolinyl group, a pyrazolidinyl group, a pyrazolinyl group, a piperidyl group, a piperazinyl group, an indolinyl group, an isoindolinyl group, a quinuclidinyl group, a morpholinyl group and a thioxantholyl group.

Specific examples of the alkylthiocarbonyl group which may have a substituent include a methylthiocarbonyl group, a propylthiocarbonyl group, a butylthiocarbonyl group, a hexylthiocarbonyl group, an octylthiocarbonyl group, a decylthiocarbonyl group, an octadecylthiocarbonyl group and a trifluoromethylthiocarbonyl group.

Specific examples of the arylthiocarbonyl group which may have a substituent include a 1-naphthylthiocarbonyl group, a 2-naphthylthiocarbonyl group, a 4-methylsulfanylphenylthiocarbonyl group, a 4-phenylsulfanylphenylthiocarbonyl group, a 4-dimethylaminophenylthiocarbonyl group, a 4-diethylaminophenylthiocarbonyl group, a 2-chlorophenylthiocarbonyl group, a 2-methylphenylthiocarbonyl group, a 2-methoxyphenylthiocarbonyl group, a 2-butoxyphenylthiocarbonyl group, a 3-chlorophenylthiocarbonyl group, a 3-trifluoromethylphenylthiocarbonyl group, a 3-cyanophenylthiocarbonyl group, a 3-nitrophenylthiocarbonyl group, a 4-fluorophenylthiocarbonyl group, a 4-cyanophenylthiocarbonyl group and a 4-methoxyphenylthiocarbonyl group.

In formula (OX-1), the monovalent substituent represented by B represents an aryl group, a heterocyclic group, an arylcarbonyl group or a heterocyclic carbonyl group. Also, these groups may have one or more substituents. As the substituent, the substituents described above are exemplified. Further, the substituent described above may be substituted with other substituent(s).

Among them, structures shown below are particularly preferred.

In the structures, Y, X and n have the same meanings as Y, X and n in formula (OX-2) described below, and preferred examples thereof are also the same.

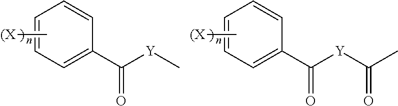

In formula (OX-1), examples of the divalent organic group represented by A include an alkylene group having from 1 to 12 carbon atoms, a cycloalkylene group and an alkynylene group. Also, these groups may have one or more substituents. As the substituent, the substituents described above are exemplified. Further, the substituent described above may be substituted with other substituent(s).

Among them, from the standpoint of increasing the sensitivity and suppressing the coloration due to heating aging, A in formula (OX-1) is preferably an unsubstituted alkylene group, an alkylene group substituted with an alkyl group (for example, a methyl group, an ethyl group, a tert-butyl group or a dodecyl group), an alkylene group substituted with an alkenyl group (for example, a vinyl group or an allyl group), or an alkylene group substituted with an aryl group (for example, a phenyl group, a p-tolyl group, a xylyl group, a cumenyl group, a naphthyl group, an anthryl group, a phenanthryl group or a styryl group).

In formula (OX-1), the aryl group represented by Ar is preferably an aryl group having from 6 to 30 carbon atoms, and may have a substituent. As the substituent, the substituents introduced into the substituted aryl group exemplified above as the specific example of the aryl group which may have a substituent may be exemplified.

Among them, from the standpoint of increasing the sensitivity and suppressing the coloration due to the heating aging, a substituted or unsubstituted phenyl group is preferred.

In formula (OX-1), from the satndpoint of the sensitivity, the structure of “SAr” formed by Ar in formula (OX-1) and S adjacent thereto is preferably the structure shown below. In the structures shown below, Me represents a methyl group, and Et represents an ethyl group.

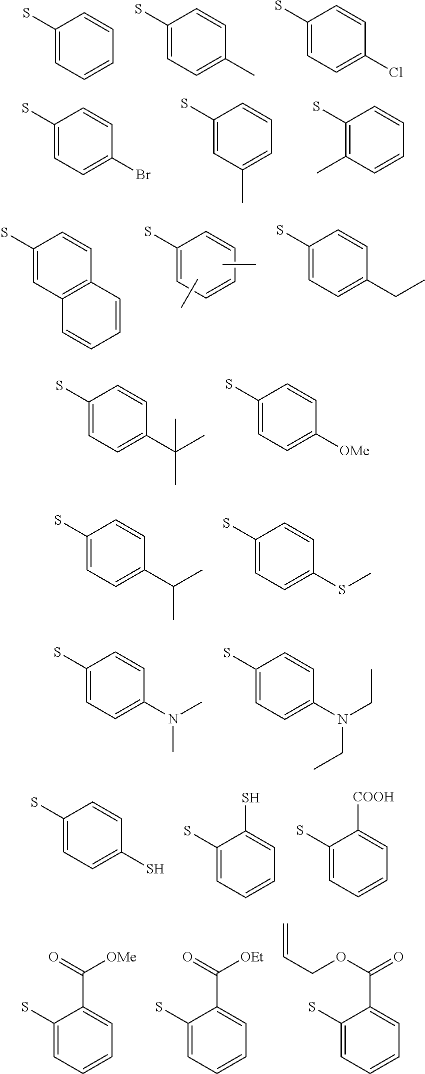

The oxime compound is preferably a compound represented by formula (OX-2) shown below.

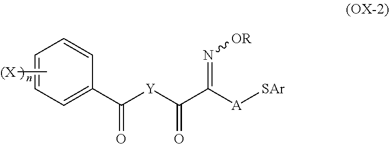

In formula (OX-2), R and X each independently represents a monovalent substituent, A and Y each independently represents a divalent organic group, Ar represents an aryl group, and n represents an integer from 0 to 5.

In formula (OX-2), R, A and Ar have the same meanings as R, A and Ar in formula (OX-1) described above, and preferred examples thereof are also the same.

In formula (OX-2), examples of the monovalent substituent represented by X include an alkyl group, an aryl group, an alkoxy group, an aryloxy group, an acyloxy group, an acyl group, an alkoxycarbonyl group, an amino group, a heterocyclic group and a halogen atom. Also, these groups may have one or more substituents. As the substituent, the substituents described above are exemplified. Further, the substituent described above may be substituted with other substituent(s).

Among them, from the standpoint of solvent solubility and improvement in absorption efficiency in the long wavelength region, X in formula (OX-2) is preferably an alkyl group.

Further, in formula (OX-2), n represents an integer of 0 to 5, and preferably an integer from 0 to 2.

In formula (OX-2), examples of the divalent organic group represented by Y include structures shown below. In the structures shown below, “*” represents a connecting cite to the carbon atom adjacent to Y in formula (OX-2).

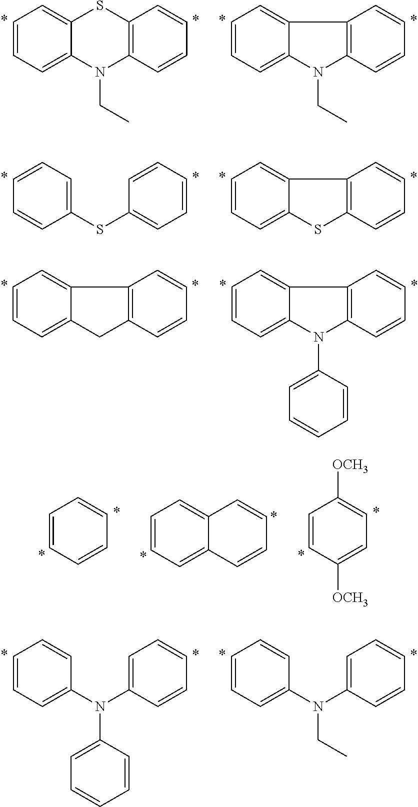

Among them, from the standpoint of high sensitivity, structures shown below are preferred.

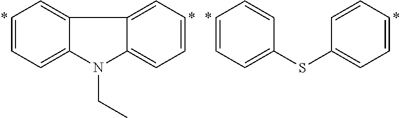

Further, the oxime compound is preferably a compound represented by formula (OX-3) shown below.

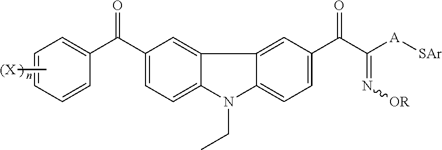

In formula (OX-3), R and X each independently represents a monovalent substituent, A represents a divalent organic group, Ar represents an aryl group, and n represents an integer from 0 to 5.

In formula (OX-3), R, X, A, Ar and n have the same meanings as R, X, A, Ar and n in formula (OX-2) described above, and preferred examples thereof are also the same.

Specific examples (B-1) to (B-10) of oxime compound which are preferably used are set forth below, but the invention should not be construed as being limited thereto.

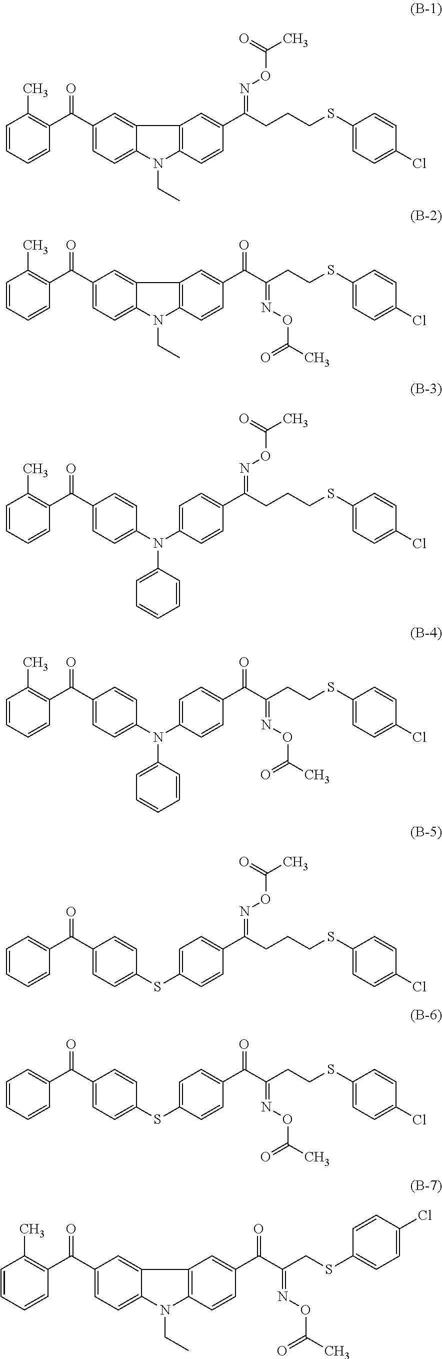

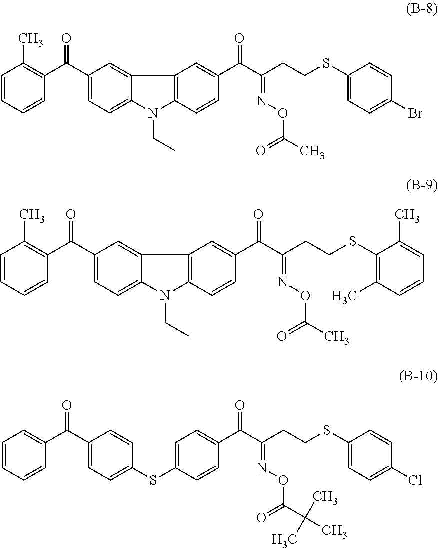 [SMILES: CCn1c2ccc(C(=O)/C(CCSc3ccc(Br)cc3)=N/OC(C)=O)cc2c2cc(C(=O)c3ccccc3C)ccc21 ; CCn1c2ccc(C(=O)/C(CCSc3c(C)cccc3C)=N/OC(C)=O)cc2c2cc(C(=O)c3ccccc3C)ccc21 ; CC(C)(C)C(=O)O/N=C(\CCSc1ccc(Cl)cc1)C(=O)c1ccc(Sc2ccc(C(=O)c3ccccc3)cc2)cc1]

The oxime compound has a maximum absorption wavelength in a wavelength region from 350 to 500 nm, preferably an absorption wavelength in a wavelength region from 360 to 480 nm, and particularly preferably a high absorbance at 365 nm and 455 nm.

The oxime compound has a molar absorption coefficient at 365 nm or 405 nm preferably from 1,000 to 300,000, more preferably from 2,000 to 300,000, particularly preferably from 5,000 to 200,000, from the standpoint of sensitivity.

The molar absorption coefficient of the compound can be measured by using a known method, and specifically, it is preferred that the molar absorption coefficient is measured, for example, by an ultraviolet and visible spectrophotometer (Carry-5 spectrophotometer, produced by Varian, Inc.) using an ethyl acetate solvent at a concentration of 0.01 g/L.

The polymerization initiators used in the invention may be used two or more thereof in combination, if desired.

From the standpoint of exposure sensitivity, the compound which generates a radical or an acid by irradiation of active light or radiation (D) is preferably a compound selected from the group consisting of a trihalomethyltriazine compound, a benzyl dimethyl ketal compound, an α-hydroxyketone compound, an α-aminoketone compound, an acyl phosphine compound, a phosphine oxide compound, a metallocene compound, an oxime compound, a triarylimidazole dimer, an onium compound, a benzothiazole compound, a benzophenone compound, an acetophenone compound and a derivative thereof, a cyclopentadiene-benzene-iron complex and a salt thereof, a halomethyloxadiazole compound and a 3-aryl-substituted coumarin compound.

A trihalomethyltriazine compound, an α-aminoketone compound, an acyl phosphine compound, a phosphine oxide compound, an oxime compound, a triarylimidazole dimer, an onium compound, a benzophenone compound or an acetophenone compound is more preferred, and at least one compound selected from the group consisting of a trihalomethyltriazine compound, an α-aminoketone compound, an oxime compound, a triarylimidazole dimer and a benzophenone compound is most preferred. It is most preferred to use an oxime compound.

Of the compounds which generate a radical or an acid by irradiation of active light or radiation (D), a compound which generates an acid having pKa of 4 or less is preferred, and a compound which generates an acid having pKa of 3 or less is more preferred.

Examples of the compound which generates an acid include a trichloromethyl-s-triazine, a sulfonium salt, an iodonium salt, a quaternary ammonium salt, a diazomethane compound, an imidosulfonate compound and an oximesulfonate compound. Of the compounds, from the standpoint of high sensitivity, an oximesulfonate compound (preferably, α-(p-toluenesulfonyloxyimino)phenylacetonitrile) is preferably used. The acid generating agents may be used individually or in combination of two or more thereof.

The acid generating agent specifically includes, acid generating agents described in Paragraph Nos. [0073] to [0095] of JP-A-2012-8223.

The content of the compound which generates a radical or an acid by irradiation of active light or radiation (D) according to the invention (total content in the case of using two or more kinds) is preferably from 0.1 to 50% by weight, more preferably from 0.1 to 30% by weight, still more preferably from 0.1 to 20% by weight, based on the total solid content of the temporary adhesive.

(E) Compound which Generates Radical or Acid by Heat

The temporary adhesive according to the invention may contain a compound which generates a radical or an acid by heat (E).

In particular, in the case where the temporary adhesive contains a polymer compound having a crosslinkable group as the polymer compound (A) or a reactive compound having a crosslinkable group as the diluent (B), the temporary adhesive preferably contains the compound which generates a radical or an acid by heat (E).

[Compound which Generates Radical by Heat]

As the compound which generates a radical by heat (hereinafter, also simply referred to as a heat radical generating agent), known heat radical generating agents can be used.

The heat radical generating agent generates a radical by energy of heat and initiates or accelerates the crosslinking reaction in the polymer compound having a crosslinkable group or in the reactive compound having a crosslinkable group. By adding the heat radical generating agent, in the case where after irradiating heat to the adhesive layer formed by using the temporary adhesive, the temporary adhesion of the member to be processed and the adhesive support is performed, the crosslinking reaction in the reactive compound having a crosslinkable group proceeds by the heat so that the adhesion property (that is, adherence property and tacking property) of the adhesive layer can be previously reduced as described in detail below.

On the other hand, in the case where after performing the temporary adhesion of the member to be processed and the adhesive support, heat is irradiated to the adhesive layer of the adhesive support, the crosslinking reaction in the reactive compound having a crosslinkable group proceeds by the heat so that the adhesive layer becomes more tough to prevent cohesion failure of the adhesive layer, which may likely occur when the member to be processed is subjected to a mechanical or chemical processing. Specifically, the adhesion property of the adhesive layer can be increased.

As a preferred heat radical generating agent, the compound which generates a radical or an acid by irradiation of active light or radiation (D) is exemplified, and a compound having a heat decomposition point ranging from 130 to 250° C., preferably from 150 to 220° C., is preferably used.

Examples of the heat radical generating agent include an aromatic ketone, an onium salt compound, an organic peroxide, a thio compound, a hexaarylbiimidazole compound, a ketoxime ester compound, a borate compound, an azinium compound, a metallocene compound, an active ester compound, a compound having a carbon-halogen bond and an azo compound. Among them, an organic peroxide and an azo compound are more preferred, and an organic peroxide (most preferably, tert-butyl peroxybenzoate) is particularly preferred.

Specifically, compounds described in Paragraph Nos. [0074] to [0118] of JP-A-2008-63554 are exemplified.

[Compound which Generates Acid by Heat]

As the compound which generates an acid by heat (hereinafter, also simply referred to as a heat acid generating agent), known heat acid generating agents can be used.

The heat acid generating agent is preferably a compound having a heat decomposition point ranging from 130 to 250° C., and more preferably from 150 to 220° C.

The heat acid generating agent includes, for example, a compound which generates an acid of low nucleophilicity, for example, a sulfonic acid, a carboxylic acid or a disulfonyl imide).

An acid generated from the heat acid generating agent includes preferably a sulfonic acid, an alkyl or aryl carboxylic acid substituted with an electron-withdrawing group and a disulfonyl imide substituted with an electron-withdrawing group, each of which has strong pKa of 2 or less. Examples of the electron-withdrawing group include a halogen atom, for example, a fluorine atom, a haloalkyl group, for example, a trifluoromethyl group, a nitro group and a cyano group.

As the heat acid generating agent, the photo acid generating agent which generates an acid by irradiation of active light or radiation (D) described above can be applied. For instance, an onium salt, for example, a sulfonium salt or an iodonium salt, an N-hydroxyimidosulfonate compound, an oxime sulfonate and an o-nitrobenzyl sulfonate are exemplified.

In the invention, it is also preferred to use a sulfonic acid ester which substantially does not generate an acid by the irradiation of active light or radiation but generates an acid by heat (more preferably, isopropyl p-toluenesulfonate).

To not substantially generate an acid by the irradiation of active light or radiation can be judged by measuring an infrared absorption (IR) spectrum or a nuclear magnetic resonance (NMR) spectrum before and after exposure of the compound and confirming that there is no change in the spectrum.

The molecular weight of the sulfonic acid ester is preferably from 230 to 1,000, and more preferably from 230 to 800.

The sulfonic acid ester which can be used in the invention may be a commercially available product or a sulfonic acid ester synthesized by a known method. The sulfonic acid ester can be synthesized, for example, by reacting a sulfonyl chloride or a sulfonic anhydride with a corresponding polyhydric alcohol under a basic condition. The heat acid generating agents may be used individually or in combination of two or more thereof.

The content of the compound which generates a radical or an acid by heat (E) in the temporary adhesive according to the invention is preferably from 0.01 to 50% by weight, more preferably from 0.1 to 20% by weight, most preferably from 0.5 to 10% by weight, based on the total solid content of the temporary adhesive, from the standpoint of reducing the adhesion property of the adhesive layer in the case of conducting the irradiation of heat before performing the temporary adhesion of the member to be processed and the adhesive support and increasing the adhesion property of the adhesive layer in the case of conducting the irradiation of heat after performing the temporary adhesion of the member to be processed and the adhesive support.

### (F) Surfactant

To the temporary adhesive according to the invention may be added various surfactants from the standpoint of more increasing the coating property. As the surfactant, various surfactants, for example, a fluorine-based surfactant, a nonionic surfactant, a cationic surfactant, an anionic surfactant or a silicone-based surfactant can be used.

In particular, by containing a fluorine-based surfactant in the temporary adhesive according to the invention, the liquid characteristic (particularly, fluidity) of a coating solution prepared is more increased, so that the uniformity of coating thickness or the liquid-saving property can be more improved.

Specifically, in the case of forming a film by using a coating solution to which the temporary adhesive containing a fluorine-based surfactant is applied, the interface tension between a surface to be coated and the coating solution is reduced, whereby wettability to the surface to be coated is improved and the coating property on the surface to be coated is increased. This is effective in that even when a thin film of about several μm is formed using a small liquid volume, formation of the film having a little thickness unevenness and uniform thickness can be performed in a preferable manner.

The fluorine content in the fluorine-based surfactant is preferably from 3 to 40% by weight, more preferably from 5 to 30% by weight, and particularly preferably from 7 to 25% by weight. The fluorine-based surfactant having a fluorine content in the range described above is effective in view of the uniformity of coating thickness and the liquid-saving property and also exhibits good solubility in the temporary adhesive.

Examples of the fluorine-based surfactant include MEGAFAC F171, MEGAFAC F172, MEGAFAC F173, MEGAFAC F176, MEGAFAC F177, MEGAFAC F141, MEGAFAC F142, MEGAFAC F143, MEGAFAC F144, MEGAFAC R30, MEGAFAC F437, MEGAFAC F475, MEGAFAC F479, MEGAFAC F482, MEGAFAC F554, MEGAFAC F780 and MEGAFAC F781 (produced by DIC Corp.), FLUORAD FC430, FLUORAD FC431 and FLUORAD FC171 (produced by Sumitomo 3M Ltd.), SURFLON S-382, SURFLON SC-101, SURFLON SC-103, SURFLON SC-104, SURFLON SC-105, SURFLON SC-1068, SURFLON SC-381, SURFLON SC-383, SURFLON 5393 and SURFLON KH-40 (produced by Asahi Glass Co., Ltd.), and PF636, PF656, PF6320, PF6520 and PF7002 (produced by OMNOVA Solutions Inc.).

Specific examples of the nonionic surfactant include glycerol, trimethylolpropane, trimethylolethane, their ethoxylate and propoxylate (for example, glycerol propoxylate or glycerol ethoxylate), polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, and a sorbitan fatty acid ester (PLURONIC L10, L31, L61, L62, 10R5, 17R2 and 25R2, TETRONIC 304, 701, 704, 901, 904 and 150R1 (produced by BASF Corp.) and SOLSPERSE 20000 (produced by The Lubrizol Corp.)).

Specific examples of the cationic surfactant include a phthalocyanine derivative (EFKA-745, produced by Morishita Sangyo K.K.), an organosiloxane polymer (KP341, produced by Shin-Etsu Chemical Co., Ltd.), a (meth)acrylic acid (co)polymer (POLYFLOW No. 75, No. 90 and No. 95 (produced by Kyoeisha Chemical Co., Ltd.) and W001 (produced by Yusho Co., Ltd.).

Specific examples of the anionic surfactant include W004, W005 and W017 (produced by Yusho Co., Ltd.).

Examples of the silicone-based surfactant include TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH30PA and TORAY SILICONE SH8400 (produced by Dow Corning Toray Co., Ltd.), TSF-4440, TSF-4300, TSF-4445, TSF-4460 and TSF-4452 (produced by Momentive Performance Materials Inc.), KP341, KF6001 and KF6002 (produced by Shin-Etsu Silicone Co., Ltd.), and BYK307, BYK323 and BYK330 (produced by BYK-Chemie GmbH).

The surfactants may be used only one kind or in combination of two or more kinds thereof.

The amount of the surfactant added is preferably from 0.001 to 2.0% by weight, more preferably from 0.005 to 1.0% by weight, based on the total solid content of the temporary adhesive.

Also, the temporary adhesive according to the invention may contain, if desired, various additives, for example, a curing agent, a curing catalyst, a polymerization inhibitor, a silane coupling agent, a filler, an adherence accelerator, an antioxidant, an ultraviolet absorber or an aggregation inhibitor as long as the effects of the invention are not impaired.

Next, the adhesive support and production method of semiconductor device using the temporary adhesive for production of semiconductor device according to the invention described above will be described.

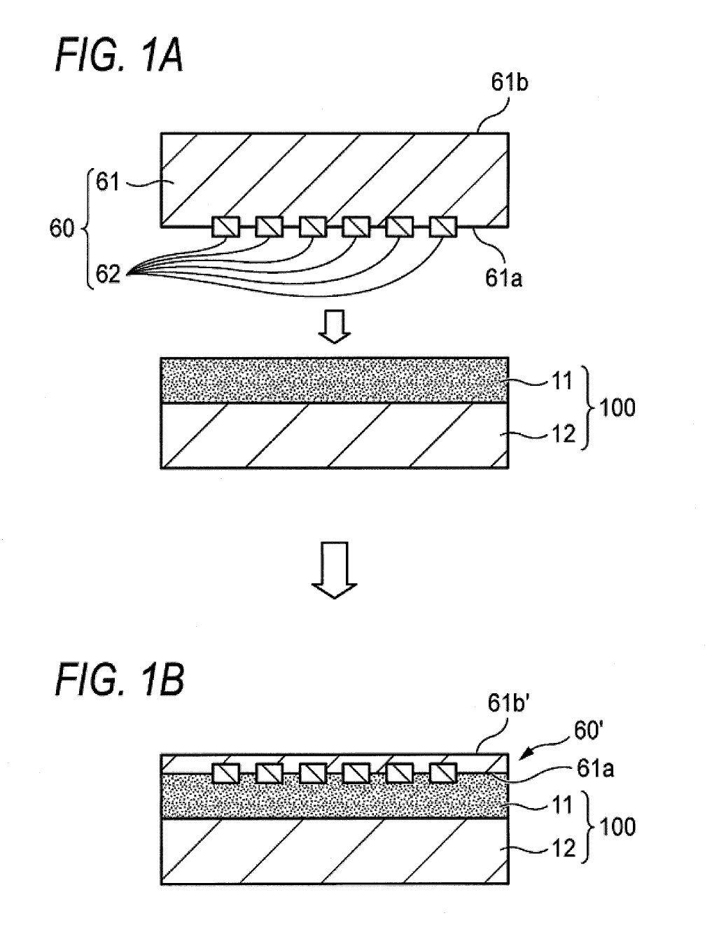

FIG. 1A and FIG. 1B are a schematic cross-sectional view illustrating temporary adhesion of an adhesive support and a device wafer and a schematic cross-sectional view showing a state in which the device wafer temporarily adhered by the adhesive substrate is thinned, respectively.

According to an embodiment of the invention, first, an adhesive support 100 having an adhesive layer 11 provided on a carrier substrate 12 is prepared as shown in FIG. 1A.

A material of the carrier substrate 12 is not particularly limited and includes, for example, a silicon substrate, a glass substrate and a metal substrate. Taking them into consideration that a silicon substrate which is typically used as a substrate of semiconductor device is hardly contaminated and that an electrostatic chuck which is commonly used in the process of producing a semiconductor device can be used, a silicon substrate is preferred.

The thickness of the carrier substrate 12 is, for example, in a range from 300 μM to 5 mm, and it is not particularly limited.

The adhesive layer 11 can be formed by coating the temporary adhesive for production of semiconductor device according to the invention on the carrier substrate 12 by using a conventionally known method, for example, a spin coating method, a spraying method, a roller coating method, a flow coating method, a doctor coating method or a dipping method, followed by drying.

The thickness of the adhesive layer 11 is, for example, in a range from 1 to 500 μm, and it is not particularly limited.

Then, temporary adhesion of the adhesive support obtained as described above and a device wafer, thinning of the device wafer and release of the device wafer from the adhesive support will be described in detail.

As shown in FIG. 1A, the device wafer 60 (member to be processed) has a plurality of device chips 62 provided on a surface 61a of silicon substrate 61.

The thickness of the silicon substrate 61 is, for example, in a range from 200 to 1,200 μm.

The surface 61a of silicon substrate 61 is pressed against the adhesive layer 11 of the adhesive support 100. Thus, the surface 61a of silicon substrate 61 and the adhesive layer 11 are adhered, whereby the adhesive support 100 and the device wafer 60 are temporarily adhered.

Also, after that, if desired, the adhesion body composed of the adhesive support 100 and the device wafer 60 may be heated (subjected to irradiation of heat), thereby making the adhesive layer more tough. Thus, since the cohesion failure of the adhesive layer, which may likely occur when the device wafer 60 is subjected to a mechanical or chemical processing described later, can be prevented, the adhesion property of the adhesive support 100 is increased. In particular, from the standpoint of accelerating the crosslinking reaction of the reactive compound having a crosslinkable group with heat, the temporary adhesive preferably contains the heat radical generating agent.

The heating temperature is preferably from 50 to 300° C.

Then, a rear surface 61b of the silicon substrate 61 is subjected to a mechanical or chemical processing, specifically, a thinning processing, for example, grinding or chemical mechanical polishing (CMP) to reduce the thickness of the silicon substrate 61 (for example, to make the thickness of 1 to 200 μm), thereby obtaining a thin device wafer 60′ as shown in FIG. 1B.

Also, as the mechanical or chemical processing, after the thinning processing a processing of forming a through hole (not shown) passing through the silicon substrate from the rear surface 61b′ of the thin device wafer 60′ and forming a though-silicone electrode (not shown) in the through hole may be performed, if desired.

Then, the surface 61a of the thin device wafer 60′ is released from the adhesive layer 11 of the adhesive support 100.

A method for the release is not particularly limited, and it is preferably performed by bringing the adhesive layer 11 into contact with an aqueous alkali solution or a release solvent and then, if desired, sliding the thin device wafer 60′ to the adhesive support 100 or stripping the thin device wafer 60′ from the adhesive support 100. Since the temporary adhesive according to the invention has a high affinity to the aqueous alkali solution or the release solvent, the temporary adhesion between the adhesive layer 11 and the surface 61a of the thin device wafer 60′ can be easily released by means of the method described above.

The aqueous alkali solution and the release solvent are described in detail below.

### [Aqueous Alkali Solution]

The aqueous alkali solution is preferably an aqueous alkali solution having pH of 14 or less, and more preferably an aqueous alkali solution having pH from 8 to 12 and containing a surfactant (anionic, cationic, nonionic or amphoteric surfactant). The aqueous alkali solution includes an aqueous solution of an inorganic alkali agent, for example, sodium tertiary phosphate, potassium tertiary phosphate, ammonium tertiary phosphate, sodium secondary phosphate, potassium secondary phosphate, ammonium secondary phosphate, sodium carbonate, potassium carbonate, ammonium carbonate, sodium hydrogen carbonate, potassium hydrogen carbonate, ammonium hydrogen carbonate, sodium borate, potassium borate, ammonium borate, sodium hydroxide, ammonium hydroxide, potassium hydroxide or lithium hydroxide. The aqueous alkali solution also includes an aqueous solution of an organic alkali agent, for example, monomethylamine, dimethylamine, trimethylamine, monoethylamine, diethylamine, triethylamine, monoisopropylamine, diisopropylamine, triisopropylamine, n-butylamine, monoethanolamine, diethanolamine, triethanolamine, monoisopropanolamine, diisopropanolamine, ethyleneimine, ethylenediamine, pyridine or tetramethylammonium hydroxide. The alkali agents may be used individually or in combination of two or more thereof.

Also, the aqueous alkali solution preferably contains a surfactant. In this case, the content of the surfactant is preferably from 0.1 to 20% by weight, more preferably from 1 to 10% by weight, based on the total weight of the aqueous alkali solution.

By controlling the content of the surfactant to the range described above, the releasing property of the thin device wafer 60′ from the adhesive support 100 tends to be more improved.

The anionic surfactant is not particularly limited, and includes, for example, fatty acid salts, abietic acid salts, hydroxyalkanesulfonic acid salts, alkanesulfonic acid salts, dialkylsulfosuccinic acid salts, straight-chain alkylbenzenesulfonic acid salts, branched alkylbenzenesulfonic acid salts, alkylnaphthalenesulfonic acid salts, alkyldiphenylether (di)sulfonic acid salts, alkylphenoxy polyoxyethylene alkylsulfonic acid salts, polyoxyethylene alkylsulfophenyl ether salts, N-alkyl-N-oleyltaurine sodium salt, N-alkylsulfosuccinic acid monoamide disodium salts, petroleum sulfonic acid salts, sulfated castor oil, sulfated beef tallow oil, sulfate ester slats of fatty acid alkyl ester, alkyl sulfate ester salts, polyoxyethylene alkyl ether sulfate ester salts, fatty acid monoglyceride sulfate ester salts, polyoxyethylene alkyl phenyl ether sulfate ester salts, polyoxyethylene styryl phenyl ether sulfate ester salts, alkyl phosphate ester salts, polyoxyethylene alkyl ether phosphate ester salts, polyoxyethylene alkyl phenyl ether phosphate ester salts, partially saponified products of styrene-maleic anhydride copolymer, partially saponified products of olefin-maleic anhydride copolymer and naphthalene sulfonate formalin condensates. Of the compounds, alkylbenzenesulfonic acid salts, alkylnaphthalenesulfonic acid salts and alkyldiphenylether (di)sulfonic acid salts are particularly preferably used.

The cationic surfactant is not particularly limited and conventionally known cationic surfactants can be used. Examples of the cationic surfactant include alkylamine salts, quaternary ammonium salts, alkylimidazolinium salts, polyoxyethylene alkyl amine salts and polyethylene polyamine derivatives.

The nonionic surfactant is not particularly limited and includes, for example, polyethylene glycol type higher alcohol ethylene oxide adducts, alkylphenol ethylene oxide adducts, alkylnaphthol ethylene oxide adducts, phenol ethylene oxide adducts, naphthol ethylene oxide adducts, fatty acid ethylene oxide adducts, polyhydric alcohol fatty acid ester ethylene oxide adducts, higher alkylamine ethylene oxide adducts, fatty acid amide ethylene oxide adducts, ethylene oxide addacts of fat, polypropylene glycol ethylene oxide adducts, dimethylsiloxane-ethylene oxide block copolymers, dimethylsiloxane-(propylene oxide-ethylene oxide) block copolymers, fatty acid esters of polyhydric alcohol type glycerol, fatty acid esters of pentaerythritol, fatty acid esters of sorbitol and sorbitan, fatty acid esters of sucrose, alkyl ethers of polyhydric alcohols and fatty acid amides of alkanolamines. Of the compounds, those having an aromatic ring and an ethylene oxide chain are preferred and alkyl-substituted or unsubstituted phenol ethylene oxide adducts and alkyl-substituted or unsubstituted naphthol ethylene oxide adducts are more preferred.

The amphoteric surfactant is not particularly limited and includes, for example, amine oxide type, for example, alkyldimethylamine oxide, betaine type, for example, alkyl betaine, and amino acid type, for example, sodium salt of alkylamino fatty acid. In particular, alkyldimethylamine oxide which may have a substituent, alkyl carboxyl betaine which may have a substituent and alkyl sulfo betaine which may have a substituent are preferably used. Specifically, compounds represented by formula (2) described in Paragraph No. [0256] of JP-A-2008-203359, compounds represented by formulae (I), (II) and (VI) described in Paragraph No. [0028] of JP-A-2008-276166 and compounds described in Paragraph Nos. [0022] to [0029] of JP-A-2009-47927 can be used.

Also, an organic solvent which is miscible with water, for example, benzyl alcohol may be added to the aqueous alkali solution, if desired. The organic solvent is suitably that having solubility in water of about 10% by weight or less, and preferably that having solubility in water of about 5% by weight or less. Examples of the organic solvent include 1-phenylethanol, 2-phenylethanol, 3-phenylpropanol, 1,4-phenylbutanol, 2,2-phenylbutanol, 1,2-phenoxyethanol, 2-benzyloxyethanol, o-methoxybenzyl alcohol, m-methoxybenzyl alcohol, p-methoxybenzyl alcohol, benzyl alcohol, cyclohexanol, 2-methylcyclohexanol, 4-methylcyclohexanol and 3-methylcyclohexanol. The content of the organic solvent is preferably from 1 to 5% by weight based on the total weight of the aqueous alkali solution. The amount of the organic solvent used has a close relationship to the amount of the surfactant used, and it is preferred that as the amount of the organic solvent is increased, the amount of the anionic surfactant is increased. This is because when a large amount of the organic solvent is used in such a state that the amount of the anionic surfactant is small, the organic solvent is not dissolved, whereby securement of good releasing property is hard to be expected.

Also, the aqueous alkali solution may further contain an additive, for example, a defoaming agent or a softening agent for hard water, if desired. Examples of the softening agent for hard water include a polyphosphate (for example, Na₂P₂O₇, Na₅P₃O₃, Na₃P₃O₉, Na₂O₄P(NaO₃P)PO₃Na₂ or Calgon (sodium polymetaphosphate)), an aminopolycarboxylic acid (for example, ethylenediaminetetraacetic acid, potassium salt thereof or sodium salt thereof, diethylenetriaminepentaacetic acid, potassium salt thereof or sodium salt thereof, triethylenetetraminehexaacetic acid, potassium salt thereof or sodium salt thereof, hydroxyethylethylenediaminetriacetic acid, potassium salt thereof or sodium salt thereof, nitrilotriacetic acid, potassium salt thereof or sodium salt thereof, 1,2-diaminocyclohexanetetraacetic acid, potassium salt thereof or sodium salt thereof, or 1,3-diamino-2-propanoltetraacetic acid, potassium salt thereof or sodium salt thereof), a polycarboxylic acid (for example, 2-phosphonobutane-1,2,4-tricarboxylic acid, potassium salt thereof or sodium salt thereof, or 2-phosphonobutane-2,3,4-tricarboxylic acid, potassium salt thereof or sodium salt thereof), an organic phosphonic acid (for example, 1-phosphonoethane-1, 2, 2-tricarboxylic acid, potassium salt thereof or sodium salt thereof, 1-hydroxyethane-1,1-diphosphonic acid, potassium salt thereof or sodium salt thereof, or aminotri(methylenephosphonic acid), potassium salt thereof or sodium salt thereof). The content of the softening agent for hard water varies depending on the hardness and the amount of water used in the aqueous alkali solution, and it is ordinarily from 0.01 to 20% by weight, preferably from 0.01 to 5% by weight, more preferably from 0.01 to 0.5% by weight, based on the total weight of the aqueous alkali solution.

Two or more kinds of the surfactants may be used in the aqueous alkali solution. Of the surfactants, from the standpoint of the releasing property, a nonionic surfactant, an amphoteric surfactant and an anionic surfactant are preferred, a nonionic surfactant and an amphoteric surfactant are more preferred, and a nonionic surfactant is most preferred.

### [Release Solvent]

As the release solvent, the solvent (C) described above can be used. From the standpoint of the releasing property, the release solvent is particularly preferably acetone, anisole, cyclohexanone, ethanolamine, hexane, N-methyl-2-pyrrolidone or a fluorine-based solvent.

Also, from the standpoint of the releasing property, the release solvent may contain the alkali agent and the surfactant described above in addition to the solvent (C) described above.

After releasing the thin device wafer 60′ from the adhesive support 100, if desired, the thin device wafer 60′ is subjected to various known processings, thereby producing a semiconductor device having the thin device wafer 60′.

Now, a conventional embodiment is described.

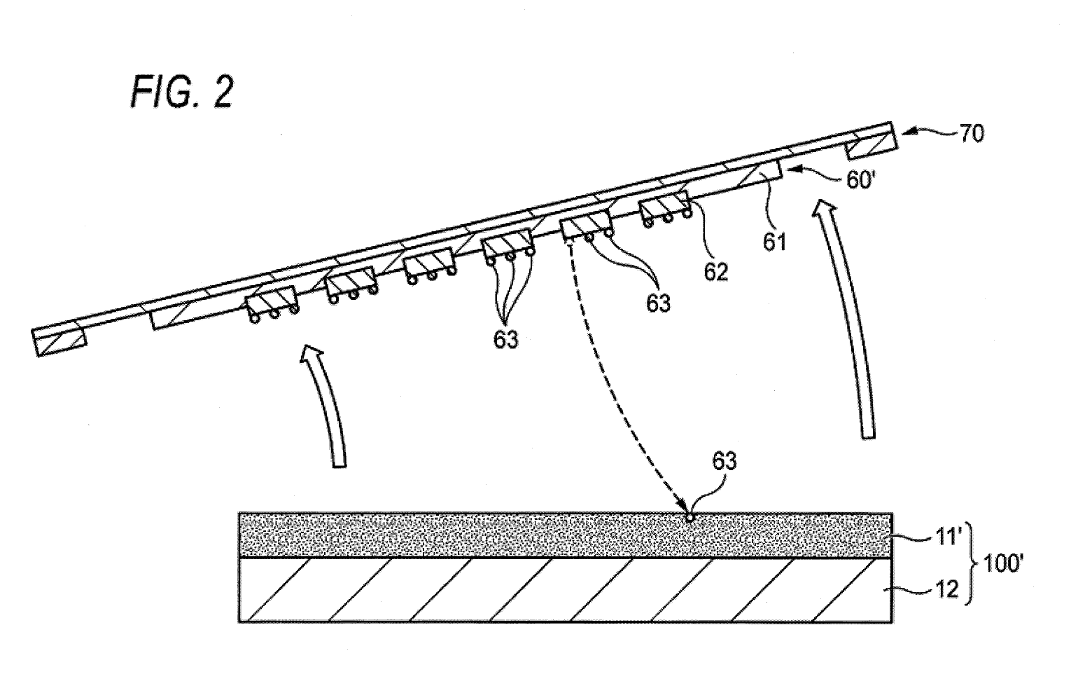

FIG. 2 is a schematic cross-sectional view illustrating release of a temporary adhering state between a conventional adhesive support and a device wafer.

In the conventional embodiment, as shown in FIG. 2, except for using as the adhesive support, an adhesive support 100′ having an adhesive layer 11′ formed from a conventional temporary adhesive provided on a carrier substrate 12, the temporary adhesion of the adhesive support 100′ to a device wafer and the thinning processing of the silicon substrate in the device wafer are performed by the same procedures as described with reference to FIG. 1A and FIG. 1B, and then a thin device wafer 60′ is released from the adhesive support 100′ by the same procedure as described with reference to FIG. 2A and FIG. 2C.

However, according to the conventional temporary adhesive it is difficult not only to temporarily support a member to be processed firmly and easily but also to easily release the temporary support for the member processed without imparting damage to the member processed. For example, when a temporary adhesive having a high adhesion property of the conventional temporary adhesives is adopted in order to perform sufficiently temporary adhesion between a device wafer and a carrier substrate, the temporary adhesion between the device wafer and the carrier substrate tends to become too strong. Thus, for example, as shown in FIG. 2, in the case where a tape (for example, a dicing tape) 70 is adhered on a rear surface 61b′ of a thin device wafer 60′ and the thin device wafer 60′ is released from the adhesive support 100′ for the purpose of releasing such a strong temporary adhesion, an inconvenience is apt to occur in that a device chip 62 is damaged, for example, a bump 63 is released from the device chip 62 having provided thereon the bump 63.

On the other hand, when a temporary adhesive having a low adhesion property of the conventional temporary adhesives is adopted, the temporary adhesion between a device wafer and a carrier substrate is too weak so that an inconvenience is apt to occur in that the device wafer cannot be firmly supported by the carrier substrate.

However, the adhesive layer formed from the temporary adhesive according to the invention exhibits a sufficient adhesion property, and the temporary adhesion between the device wafer 60 and the adhesive support 100 can be easily released particularly by bringing the adhesive layer 11 into contact with an aqueous alkali solution or a release solvent. Specifically, due to the temporary adhesive according to the invention, not only the device wafer 60 can temporarily support firmly and easily but also the temporary support for the thin device wafer 60′ can be easily released without imparting damage to the thin device wafer 60′.

Further, particularly in the case where the temporary adhesive according to the invention further contains the compound which generates a radical or an acid by irradiation of active light or radiation (D) or the compound which generates a radical or an acid by heat (E) and also the diluent (B) is the reactive compound capable of crosslinking by an action of a radical or an acid, the adhesive layer 11 can be made as an adhesive layer in which the adhesion property decreases by the irradiation of active light or radiation, or heat. Specifically, the adhesive layer can be made as a layer which has an adhesive property before being subjected to the irradiation of active light or radiation, or heat and in which the adhesion property is decreased or lost in the region to which active light or radiation, or heat is irradiated.

Therefore, according to the invention, before adhering the adhesive support 100 to the device wafer 60, active light or radiation, or heat may be irradiated to a surface of the adhesive surface 11 of the adhesive support 100, which is to be adhered to the device wafer 60.

For example, the adhesive layer is converted to an adhesive layer in which a low adhesive region and a high adhesive region are formed by the irradiation of active light or radiation, or heat, and then temporary adhesion of the adhesive support to the member to be processed may be performed. This embodiment described below.

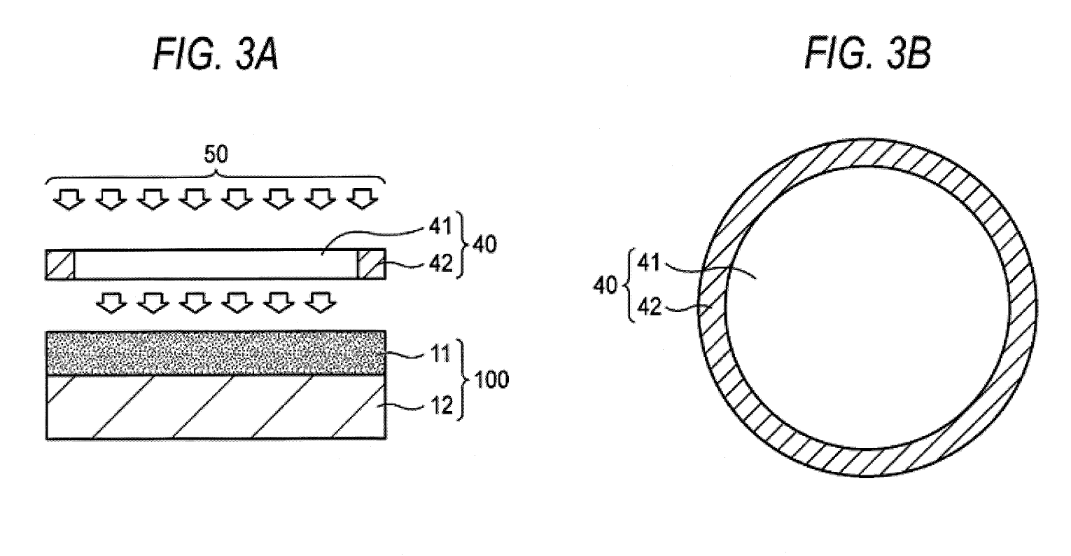

FIG. 3A shows a schematic cross-sectional view illustrating exposure of the adhesive support, and FIG. 3B shows a schematic top view of a mask.

First, the adhesive layer 11 of the adhesive support 100 is irradiated by active light or radiation 50 (that is exposed) through a mask 40.

As shown in FIG. 3A and FIG. 3B, the mask 40 is composed of a light-transmitting region 41 provided in the central area and a light-shielding region 42 provided in the peripheral area.

Thus, the exposure described above is a pattern exposure in which the central area of the adhesive layer 11 is exposed, but the peripheral area surrounding the central area is not exposed.

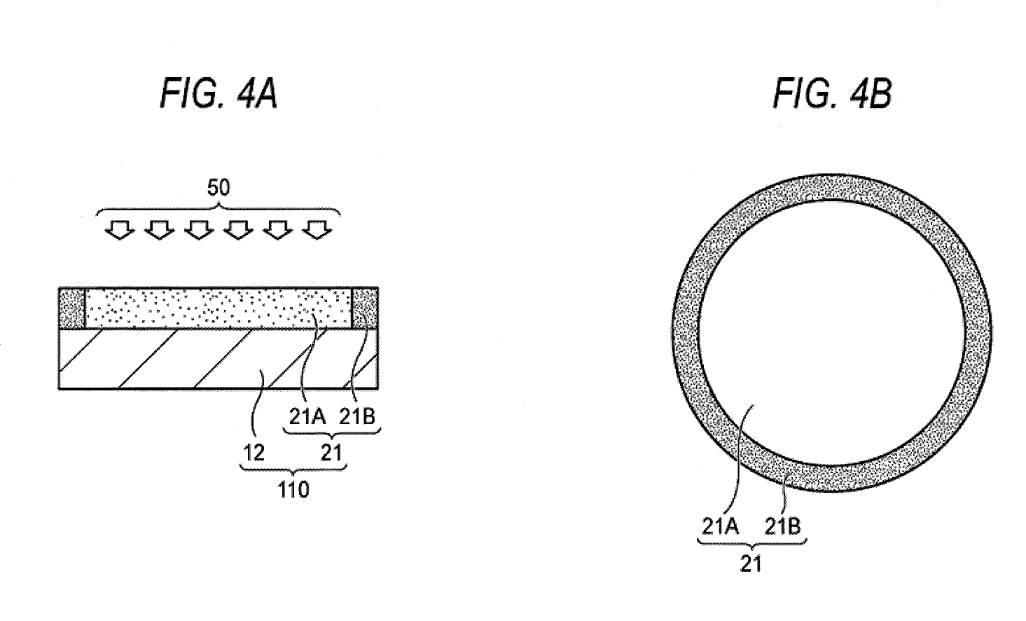

FIG. 4A shows a schematic cross-sectional view of the adhesive support subjected to pattern exposure, and FIG. 4B shows a schematic top view of the adhesive support subjected to pattern exposure.

As described above, in the case where the adhesive layer 11 is an adhesive layer in which the adhesion property decreases by the irradiation of active light or radiation, the adhesive support 100 is converted to an adhesive support 110 having an adhesive layer 21 in which a low adhesive region 21A and a high adhesive region 21B are formed in the central area and the peripheral area, respectively, as shown in FIG. 4A and FIG. 4B.

In the specification, the term “low adhesive region” means a region having a low adhesion property in comparison with the “high adhesive region” and includes a region having no adhesion property (specifically, a “non-adhesive region”). Similarly, the term “high adhesive region” means a region having a high adhesion property in comparison with the “low adhesive region”.

In the adhesive support 110, the low adhesive region 21A and the high adhesive region 21B are provided by the pattern exposure using the mask 40, the respective areas and shapes of the light-transmitting region and the light-shielding region in the mask 40 can be controlled in an order of micron to nanometer. Thus, since the respective areas and shapes of the high adhesive region 21B and the low adhesive region 21A formed in the adhesive layer 21 of the adhesive support 110 can be finely controlled by the pattern exposure, the adhesion property of the adhesive layer as a whole can be controlled in a high accuracy and easily to an adhesive property in such a degree that not only the silicon substrate 61 of the device wafer 60 is temporarily supported more firmly and easily but also the temporary support for the silicon substrate of the thin display wafer 60′ is more easily released without imparting damage to the thin display wafer 60′.

Also, in the high adhesive region 21B and the low adhesive region 21A in the adhesive support 110, the surface properties thereof are differentiated by the pattern exposure, but they are integrated as a structure. Therefore, there is no large difference in the mechanical properties between the high adhesive region 21B and the low adhesive region 21A, and even when the surface 61a of the silicon substrate 61 of the device wafer 60 is adhered to the adhesive layer 21 of the adhesive support 110, and then the rear surface 61b of the silicon substrate 61 is subjected to the thinning processing or the processing for forming a through-silicone electrode, a difference in the pressure relating to the processing (for example, grinding pressure or a polishing pressure) hardly arises between the region of the back surface 61b corresponding to the high adhesive region 21B of the adhesive layer 21 and the region of the back surface 61b corresponding to the low adhesive region 21A, and the influence of the high adhesive region 21B and the low adhesive region 21A on the processing accuracy in the processing described above is small. This is particularly effective in the case of obtaining a thin device wafer 60′ having a thickness, for example, from 1 to 200 μm, which is likely to cause the problem described above.

Therefore, the embodiment using the adhesive support 110 is preferred as an embodiment wherein the silicon substrate 61 can be temporarily supported more firmly and easily while suppressing the influence on the processing accuracy when the silicon substrate 61 of the device wafer 60 is subjected to the processing described above and the temporary support for the thin display wafer 60′ can be more easily released without imparting damage to the thin display wafer 60′.

Also, in the case where the adhesive layer 11 is an adhesive layer in which the adhesion property decreases by the irradiation of active light or radiation, or heat, the adhesive layer is converted to an adhesive layer in which the adhesion property decreases towards the outer surface from the inner surface on the substrate side by the irradiation of active light or radiation, or heat, and then temporary adhesion of the adhesive support to the member to be processed may be performed. This embodiment described below.

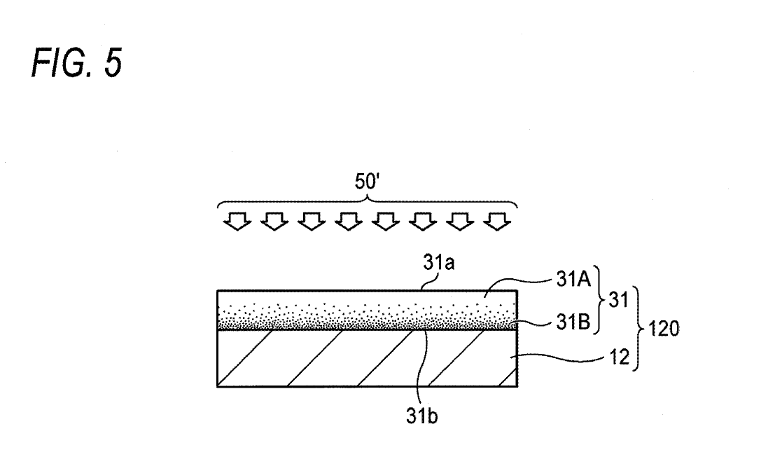

FIG. 5 is a schematic cross-sectional view illustrating irradiation of active light or radiation, or heat to the adhesive support.

First, active light or radiation, or heat 50′ is irradiated toward the outer surface of the adhesive layer 11, whereby the adhesive support 100 is converted into an adhesive support 120 having an adhesive layer 31 in which the adhesion property is decreased toward the outer surface 31a from the inner surface 31b on the substrate side, as shown in FIG. 5.

Specifically, the adhesive layer 31 comes to have a low adhesive region 31A and a high adhesive region 31B on the outer surface 31a side and the inner surface 31b side, respectively.

Such an adhesive layer 31 can be easily formed by controlling the irradiation dose of the active light or radiation, or heat 50′ to such an irradiation dose that the active light or radiation, or heat 50′ sufficiently irradiates the outer surface 31a, but the active light or radiation, or heat 50′ does not reach to the inner surface 31b.

The change in the irradiation dose as described above can be easily performed by changing the setting of an exposure machine or a heating device so that not only the cost of equipment can be reduced but also formation of the adhesive layer 31 can be performed without spending a long time.

Also, in the embodiment according to the invention described above, the adhesive layer 31 which is integral as a structure but is positively caused to have lower adhesion property on the outer surface 31a than the adhesion property on the inner surface 31b is formed by combining the adhesive layer 11 and the irradiation method and therefore, another layer, for example, a separating layer need not be provided.

As described above, the formation of the adhesive layer 31 is easy.

Further, each of the adhesion property on the outer surface 31a and the adhesion property on the inner surface 31b can be controlled with good precision, for example, by selecting the material constituting the adhesive layer 11 and adjusting the irradiation dose of the active light, radiation or heat.

As a result, the adhesion property of the adhesive layer 31 to each of the substrate 12 and the silicon substrate 61 can be easily controlled with high precision to such a degree of adhesion property that not only the silicon substrate 61 of the device wafer 60 can be temporarily supported firmly and easily but also the temporary support for the silicon substrate of the thin device wafer 60′ can be easily released without imparting damage to the thin device wafer 60′.

Therefore, the embodiment using the adhesive support 120 is also preferred as an embodiment wherein not only the silicon substrate 61 can be temporarily supported more firmly and easily when the silicon substrate 61 of the device wafer 60 is subjected to the processing described above but also the temporary support for the thin display wafer 60′ can be more easily released without imparting damage to the thin display wafer 60′.

The production method of semiconductor device according to the invention is not limited to the embodiments described above, and appropriate modifications, improvements and the like can be made therein.

In the embodiments described above, the adhesive layer formed from the temporary adhesive according to the invention is provided on the carrier substrate before the temporary adhesion of a device wafer to constitute the adhesive support, but the adhesive layer may be formed on a member to be processed, for example, a device wafer and then the member to be processed having the adhesive layer provided thereon may be temporary adhered to the substrate.

For example, a mask used for the pattern exposure may be a binary mask or a halftone mask.

Also, the exposure is mask exposure through a mask, but may be selective exposure by drawing using also an electron beam or the like.

In the embodiments described above, the adhesive layer has a single-layer structure, but the adhesive layer may have a multilayer structure. Examples of the method for forming an adhesive layer having a multilayer structure include a method of stepwise coating an adhesive composition by the conventionally known method described above before irradiation of active light or radiation, and a method of coating an adhesive composition by the conventionally known method described above after irradiation of active light or radiation. In the embodiment where the adhesive layer has a multilayer structure, for example, in the case where the adhesive layer 11 is an adhesive layer in which the adhesion property decreases by the irradiation of active light or radiation, or heat, the adhesion property as an entire adhesive layer can also be decreased by decreasing the adhesion property between respective layers by the irradiation of active light or radiation, or heat.

In the embodiments described above, the member to be processed which is supported by the adhesive support is a silicon substrate, but the member to be processed is not limited thereto and may be any member to be processed which can be subjected to a mechanical or chemical processing in the production method of semiconductor device.

For example, the member to be processed includes a compound semiconductor substrate, and specific examples of the compound semiconductor substrate include an SiC substrate, an SiGe substrate, a ZnS substrate, a ZnSe substrate, a GaAs substrate, an InP substrate and a GaN substrate.

Further, in the embodiments described above, the mechanical or chemical processing applied to the silicon substrate which is supported by the adhesive support is the thinning processing of the silicon substrate or the processing for forming a through-silicon electrode, but the mechanical or chemical processing is not limited thereto and may be any processing required in the production method of semiconductor device.

In addition, the light-transmitting region and the light-shielding region in the mask, the high adhesive region and the low adhesive region in the adhesive layer, and the shape, dimension, number, arrangement portion and the like of device chip in the device wafer, which are exemplified in the embodiments described above, are arbitrary and not limited as long as the invention can be achieved.

### EXAMPLES

The invention will be described more specifically with reference to the examples, but the invention should not be construed as being limited thereto as long as the gist of the invention is not deviated. All “part” and “%” therein are weigh basis unless otherwise specified.

### <Formation of Adhesive Support>

Each liquid adhesive composition having the composition shown in Table 1 below was coated on a 4-inch Si wafer by a spin coater (Opticoat MS-A100, produced by Mikasa Co., Ltd., 1,200 rpm, 30 seconds) and then baked at 100° C. for 30 seconds to form Wafer 1 having provided thereon an adhesive layer having a thickness of 10 μm (that is, an adhesive support).

TABLE 1

| | | | | | Photo Acid | | | |
|---|---|---|---|---|---|---|---|---|
| | Polymer Compound | | Diluent | | Generating Agent | | Photo Radical Generating Agent | |
| | | Parts by | | Parts by | | Parts by | | Parts by |
| | Kind | Weight | Kind | Weight | Kind | Weight | Kind | Weight |
| Liquid Adhesive | Polymer Compound (1) | 20 | Diluent | 20 | — | 0 | Photo Radical | 2 |
| Composition (1) | | | (2) | | | | Generating Agent (1) | |
| Liquid Adhesive | Polymer Compound (2) | 20 | Diluent | 20 | — | 0 | Photo Radical | 2 |
| Composition (2) | | | (2) | | | | Generating Agent (1) | |
| Liquid Adhesive | Polymer Compound (3) | 20 | Diluent | 20 | — | 0 | Photo Radical | 2 |
| Composition (3) | | | (2) | | | | Generating Agent (1) | |
| Liquid Adhesive | Polymer Compound (4) | 20 | Diluent | 20 | — | 0 | Photo Radical | 2 |
| Composition (4) | | | (2) | | | | Generating Agent (1) | |
| Liquid Adhesive | Polymer Compound (1) | 20 | Diluent | 20 | — | 0 | Photo Radical | 2 |
| Composition (5) | | | (1) | | | | Generating Agent (1) | |
| Liquid Adhesive | Polymer Compound (1) | 30 | Diluent | 10 | — | 0 | Photo Radical | 2 |
| Composition (6) | | | (2) | | | | Generating Agent (1) | |
| Liquid Adhesive | Polymer Compound (1) | 20 | Diluent | 20 | — | 0 | Photo Radical | 2 |
| Composition (7) | | | (3) | | | | Generating Agent (1) | |
| Liquid Adhesive | Polymer Compound (1) | 20 | Diluent | 20 | Photo | 2 | — | 0 |
| Composition (8) | | | (4) | | Acid | | | |
| | | | | | Generating | | | |
| | | | | | Agent (1) | | | |
| Liquid Adhesive | Polymer Compound (1) | 10 | Diluent | 30 | — | 0 | Photo Radical | 2 |
| Composition (9) | | | (2) | | | | Generating Agent (1) | |
| Liquid Adhesive | Polymer Compound (1) | 20 | Diluent | 20 | — | 0 | Photo Radical | 2 |
| Composition (10) | | | (2) | | | | Generating Agent (1) | |
| Liquid Adhesive | Polymer Compound (2) | 20 | Diluent | 20 | — | 0 | Photo Radical | 2 |
| Composition (11) | | | (2) | | | | Generating Agent (1) | |
| Liquid Adhesive | Polymer Compound (3) | 20 | Diluent | 20 | — | 0 | Photo Radical | 2 |
| Composition (12) | | | (2) | | | | Generating Agent (1) | |
| Liquid Adhesive | Polymer Compound (4) | 20 | Diluent | 20 | — | 0 | Photo Radical | 2 |
| Composition (13) | | | (2) | | | | Generating Agent (1) | |
| Liquid Adhesive | Polymer Compound (1) | 20 | Diluent | 20 | Photo | 2 | — | 0 |
| Composition (14) | | | (4) | | Acid | | | |
| | | | | | Generating | | | |
| | | | | | Agent (1) | | | |
| Liquid Adhesive | Polymer Compound (1) | 20 | Diluent | 20 | — | 0 | Photo Radical | 2 |
| Composition (15) | | | (2) | | | | Generating Agent (1) | |
| Liquid Adhesive | Polymer Compound (1) | 20 | Diluent | 20 | — | 0 | Photo Radical | 2 |
| Composition (16) | | | (2) | | | | Generating Agent (1) | |
| Liquid Adhesive | Polymer Compound (1) | 20 | Diluent | 20 | — | 0 | — | 0 |
| Composition (17) | | | (2) | | | | | |
| Liquid Adhesive | Polymer Compound (1) | 20 | Diluent | 20 | — | 0 | — | 0 |
| Composition (18) | | | (1) | | | | | |
| Liquid Adhesive | Polymer Compound (1) for | 20 | Diluent | 20 | — | 0 | — | 0 |
| Composition (1) for | Comparative Example | | (1) | | | | | |
| Comparative Example | | | | | | | | |
| Liquid Adhesive | Polymer Compound (2) for | 20 | Diluent | 20 | — | 0 | — | 0 |
| Composition (2) for | Comparative Example | | (1) | | | | | |
| Comparative Example | | | | | | | | |
| Liquid Adhesive | Polymer Compound (3) for | 20 | Diluent | 20 | — | 0 | — | 0 |
| Composition (3) for | Comparative Example | | (1) | | | | | |
| Comparative Example | | | | | | | | |

| | | | | | Solvent | |
|---|---|---|---|---|---|---|
| | Heat Acid Generating Agent | | Heat Radical Generating Agent | | | Parts by |
| | Kind | Parts by Weight | Kind | Parts by Weight | Kind | Weight |
| Liquid Adhesive Composition (1) | — | 0 | — | 0 | Solvent (1) | 60 |
| Liquid Adhesive Composition (2) | — | 0 | — | 0 | Solvent (1) | 60 |
| Liquid Adhesive Composition (3) | — | 0 | — | 0 | Solvent (1) | 60 |
| Liquid Adhesive Composition (4) | — | 0 | — | 0 | Solvent (1) | 60 |
| Liquid Adhesive Composition (5) | — | 0 | — | 0 | Solvent (1) | 60 |
| Liquid Adhesive Composition (6) | — | 0 | — | 0 | Solvent (1) | 60 |
| Liquid Adhesive Composition (7) | — | 0 | — | 0 | Solvent (1) | 60 |
| Liquid Adhesive Composition (8) | — | 0 | — | 0 | Solvent (1) | 60 |
| Liquid Adhesive Composition (9) | — | 0 | — | 0 | Solvent (1) | 60 |
| Liquid Adhesive Composition (10) | — | 0 | Heat Radical Generating | 2 | Solvent (1) | 60 |
| | | | Agent (1) | | | |
| Liquid Adhesive Composition (11) | — | 0 | Heat Radical Generating | 2 | Solvent (1) | 60 |
| | | | Agent (1) | | | |
| Liquid Adhesive Composition (12) | — | 0 | Heat Radical Generating | 2 | Solvent (1) | 60 |
| | | | Agent (1) | | | |
| Liquid Adhesive Composition (13) | — | 0 | Heat Radical Generating | 2 | Solvent (1) | 60 |
| | | | Agent (1) | | | |
| Liquid Adhesive Composition (14) | Heat Acid | 2 | — | 0 | Solvent (1) | 60 |
| | Generating | | | | | |
| | Agent (1) | | | | | |
| Liquid Adhesive Composition (15) | — | 0 | — | 0 | Solvent (2) | 60 |
| Liquid Adhesive Composition (16) | — | 0 | — | 0 | Solvent (3) | 60 |
| Liquid Adhesive Composition (17) | — | 0 | — | 0 | Solvent (1) | 60 |
| Liquid Adhesive Composition (18) | — | 0 | — | 0 | Solvent (1) | 60 |
| Liquid Adhesive | — | 0 | — | 0 | Solvent (1) | 60 |
| Composition (1) for | | | | | | |
| Comparative Example | | | | | | |
| Liquid Adhesive | — | 0 | — | 0 | Solvent (1) | 60 |
| Composition (2) for | | | | | | |
| Comparative Example | | | | | | |
| Liquid Adhesive | — | 0 | — | 0 | Solvent (1) | 60 |
| Composition (3) for | | | | | | |
| Comparative Example | | | | | | |

The compounds shown in Table 1 are as follows.

### [(A) Polymer Compound Having Acid Group]

### Polymer Compound (1):

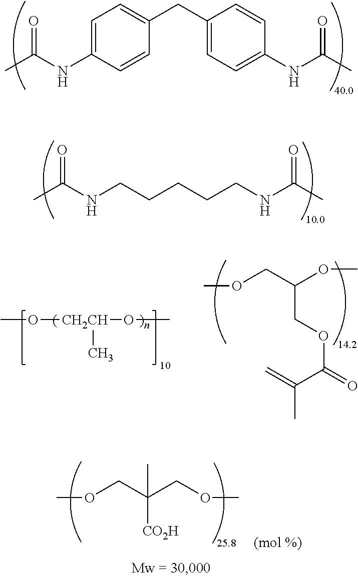

Polymer Compound (2): NK Oligo EA7440 (produced by Shin-Nakamura Co., Ltd., novolac resin having a carboxylic acid group and a radical polymerizable group)

### Polymer Compound (3):

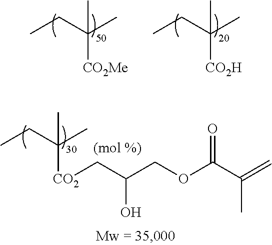

### Polymer Compound (4):

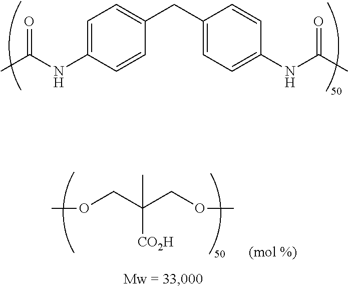

### [(B) Diluent]

Diluent (1): Glycerol (produced by Tokyo Chemical Industry Co., Ltd.)
Diluent (2): UA-1100H (produced by Shin-Nakamura Chemical Co., Ltd., tetrafunctional urethane acrylate)
Diluent (3): A-TMPT (produced by Shin-Nakamura Chemical Co., Ltd., trimethylolpropane triacrylate)
Diluent (4): 2,2-Bis(4-glycidyloxyphenyl)propane (produced by Tokyo Chemical Industry Co., Ltd.)

### [(C) Solvent]

Solvent (1): 1-Methoxy-2-propanol acetate

### Solvent (2): 2-Butanone

### Solvent (3): 2-Heptanone

[(D) Compound which Generates Radical or Acid by Irradiation of Active Light or Radiation]
Photo Acid Generating Agent (1): α-(p-Toluenesulfonyloxyimino)phenyl acetonitrile
Photo Radical Generating Agent (1): IRGACURE OXE 02 (produced by Ciba Specialty Chemicals Inc.)
[(E) Compound which Generates Radical or Acid by Heat]
Heat Acid Generating Agent (1): Isopropyl p-toluenesulfonate (produced by Tokyo Chemical Industry Co., Ltd.)
Heat Radical Generating Agent (1): Perbutyl Z (produced by NOF Corp, tert-Butyl peroxybenzoate)

### Polymer Compound for Comparative Example

### Polymer Compound (1) for Comparative Example

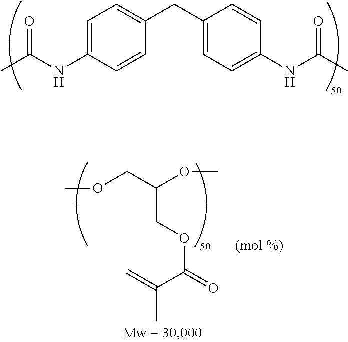

Polymer Compound (2) for Comparative Example: RB810 (produced by JSR Corp., syndiotactic 1,2-polybutadiene
Polymer Compound (3) for Comparative Example: CAB-551-0.2 (produced by Eastman Chemical Co., cellulose acetate butyrate)

### <Preparation of Adhesion Property Test Piece>

Using the temporary adhesive composed of each liquid adhesive composition as shown in Tables 2 and 3 below, each process of “exposure”, “bonding with pressure” and “baking” were conducted in this order to prepare an adhesion property test piece. In Tables 2 and 3, the process indicated as “Absence” means that the test piece was not subjected to the process and moved to the next process.

### [Exposure]

From the adhesive layer side of Wafer 1, a central portion of the adhesive layer excluding an outer peripheral portion of 5 mm was exposed through a mask protecting (shielding) the outer peripheral portion of 5 mm of the adhesive layer using an UV exposure device (LC8, produced by Hamamatsu Photonics K.K.) with light having a wavelength of 254 nm at an exposure dose of 100 mJ/cm².

[Bonding with Pressure]

A 4-inch Si wafer having no coating on its surface thereof (hereinafter, referred to as Wafer 2) was superimposed on the adhesive layer of Wafer 1 and adhered under pressure of 20N/cm² at 25° C. for 30 seconds.

### [Baking]

Wafer 1 and wafer 2 adhered were heated at 180° C. for 60 seconds.

### <Adhesive Force Measurement of Adhesion Property Test Piece>

As to the shear adhesive force of the adhesion property test piece prepared under the conditions described in Tables 2 and 3, tensile measurement was performed in the direction along the surface of the adhesive layer under the condition of 250 mm/min using a tensile tester (produced by Imada Co., Ltd.). The results are shown in Tables 2 and 3 below.

### <Preparation of Releasing Property Test Piece>

The test piece prepared under the conditions described in Tables 2 and 3 was immersed in an aqueous alkali solution or a release solvent described in Tables 2 and 3 at 25° C. for 10 minutes. The test piece was taken from the aqueous alkali solution or the release solvent, washed carefully with pure water, and dried at 25° C. The aqueous alkali solution and the release solvent used are as follows.

| | | |
|---|---|---|
| Tetramethylammonium hydroxide (produced by | 10.0 | parts by weight |
| Tokyo Chemical Industry Co., Ltd.) | | |
| NEWCOL B-13 (nonionic surfactant, produced | 1.0 | part by weight |
| by Nippon Nyukazai Co., Ltd.) | | |
| Pure water | 89.0 | parts by weight |

### <Aqueous Alkali Solution (2)>

| | | |
|---|---|---|
| Tetramethylammonium hydroxide (produced by | 2.4 | parts by weight |
| Tokyo Chemical Industry Co., Ltd.) | | |
| NEWCOL B-13 (nonionic surfactant, produced | 1.0 | part by weight |
| by Nippon Nyukazai Co., Ltd.) | | |
| Pure water | 96.6 | parts by weight |

### <Aqueous Alkali Solution (3)>

| | | |
|---|---|---|
| Tetramethylammonium hydroxide (produced by | 2.4 | parts by weight |
| Tokyo Chemical Industry Co., Ltd.) | | |
| NEWCOL B-13 (nonionic surfactant, produced | 10.0 | part by weight |
| by Nippon Nyukazai Co., Ltd.) | | |
| Pure water | 87.6 | parts by weight |

### <Aqueous Alkali Solution (4)>

| | | |
|---|---|---|
| Potassium hydroxide (produced by | 1.5 | parts by weight |
| Wako Pure Chemical Industries, Ltd.) | | |
| NEWCOL B-13 (nonionic surfactant, produced | 1.0 | part by weight |
| by Nippon Nyukazai Co., Ltd.) | | |
| Pure water | 97.5 | parts by weight |

### <Aqueous Alkali Solution (5)>

| | | |
|---|---|---|
| Tetramethylammonium hydroxide (produced by | 2.4 | parts by weight |
| Tokyo Chemical Industry Co., Ltd.) | | |
| Pure water | 97.6 | parts by weight |

### [Release Solvent]

Release solvent (1): Acetone
Release solvent (2): Anisole
Release solvent (3): Cyclohexanone
Release solvent (4): Ethanolamine
Release solvent (5): Hexane
Release solvent (6): ZEOROLA (fluorine-based solvent, produced by Zeon Corp.)

### <Adhesive Force Measurement of Releasing Property Test Piece>

As to the shear adhesive force of the releasing property test piece prepared under the conditions described in Tables 2 and 3, tensile measurement was performed in the direction along the surface of the adhesive layer under the condition of 250 mm/min using a tensile tester (produced by Imada Co., Ltd.). The results are shown in Tables 2 and 3 below.

TABLE 2

| | | | | | Result of | | Result of |
|---|---|---|---|---|---|---|---|
| | | | | | Adhesive Force | Releasing Property | Adhesive Force |
| | | Adhesion Property Test Piece | | | Measurement | Test Piece | Measurement |
| | Liquid Adhesive | | Bonding | | Adhesion Property | Kind of Release | Releasing Property |
| | Composition | Exposure | with Pressure | Baking | (N/25 mm²) | Solution | (N/25 mm²) |
| Example 1 | (1) | Presence | Presence | Absence | 30 | Aqueous Alkali | 1 |
| | | | | | | Solution (1) | |
| Example 2 | | | | | | Aqueous Alkali | 2 |
| | | | | | | Solution (2) | |
| Example 3 | | | | | | Aqueous Alkali | 1 |
| | | | | | | Solution (3) | |
| Example 4 | | | | | | Aqueous Alkali | 1.5 |
| | | | | | | Solution (4) | |
| Example 5 | | | | | | Aqueous Alkali | 10 |
| | | | | | | Solution (5) | |
| Example 6 | | | | | | Release Solvent (1) | 5 |
| Example 7 | | | | | | Release Solvent (2) | 3 |
| Example 8 | | | | | | Release Solvent (3) | 3 |
| Example 9 | | | | | | Release Solvent (4) | 4 |
| Example | | | | | | Release Solvent (5) | 3 |
| 10 | | | | | | | |
| Example | | | | | | Release Solvent (6) | 3 |
| 11 | | | | | | | |
| Example | (2) | Presence | Presence | Absence | 30 | Aqueous Alkali | 1 |
| 12 | | | | | | Solution (1) | |
| Example | (3) | Presence | Presence | Absence | 25 | Aqueous Alkali | 8 |
| 13 | | | | | | Solution (1) | |
| Example | (4) | Presence | Presence | Absence | 40 | Aqueous Alkali | 10 |
| 14 | | | | | | Solution (1) | |
| Example | (5) | Presence | Presence | Absence | 20 | Aqueous Alkali | 2 |
| 15 | | | | | | Solution (1) | |
| Example | (6) | Presence | Presence | Absence | 20 | Aqueous Alkali | 1 |
| 16 | | | | | | Solution (1) | |
| Example | (7) | Presence | Presence | Absence | 15 | Aqueous Alkali | 1 |
| 17 | | | | | | Solution (1) | |
| Example | (8) | Presence | Presence | Absence | 15 | Aqueous Alkali | 3 |
| 18 | | | | | | Solution (1) | |
| Example | (9) | Presence | Presence | Presence | 35 | Aqueous Alkali | 2 |
| 19 | | | | | | Solution (1) | |

TABLE 3

| | | | | | | | Result of |
|---|---|---|---|---|---|---|---|
| | | | | | | | Adhesive |
| | | | | Result of Adhesive Force | | | Force |
| | | | | Measurement | | | Measurement |
| | | Adhesion Property Test Piece | | | Adhesion | Releasing Property Test | Releasing |
| | | | Bonding with | | Property | Piece | Property |
| | Liquid Adhesive Composition | Exposure | Pressure | Baking | (N/25 mm²) | Kind of Release Solution | (N/25 mm²) |
| Example 20 | (10) | Presence | Presence | Presence | 50 | Aqueous Alkali Solution (1) | 5 |
| Example 21 | | | | | | Aqueous Alkali Solution (2) | 8 |
| Example 22 | | | | | | Aqueous Alkali Solution (3) | 5 |
| Example 23 | | | | | | Aqueous Alkali Solution (4) | 6.5 |
| Example 24 | | | | | | Aqueous Alkali Solution (5) | 15 |
| Example 25 | | | | | | Release Solvent (1) | 10 |
| Example 26 | | | | | | Release Solvent (2) | 8 |
| Example 27 | | | | | | Release Solvent (3) | 8 |
| Example 28 | | | | | | Release Solvent (4) | 9 |
| Example 29 | | | | | | Release Solvent (5) | 8 |
| Example 30 | | | | | | Release Solvent (6) | 8 |
| Example 31 | (11) | Presence | Presence | Presence | 50 | Aqueous Alkali Solution (1) | 5 |
| Example 32 | (12) | Presence | Presence | Presence | 30 | Aqueous Alkali Solution (1) | 10 |
| Example 33 | (13) | Presence | Presence | Presence | 50 | Aqueous Alkali Solution (1) | 15 |
| Example 34 | (14) | Presence | Presence | Presence | 35 | Aqueous Alkali Solution (1) | 13 |
| Example 35 | (15) | Presence | Presence | Presence | 50 | Aqueous Alkali Solution (1) | 5 |
| Example 36 | (16) | Presence | Presence | Presence | 50 | Aqueous Alkali Solution (1) | 5 |
| Example 37 | (1) | Absence | Presence | Absence | 50 | Aqueous Alkali Solution (1) | 30 |
| Example 38 | (2) | Absence | Presence | Absence | 50 | Aqueous Alkali Solution (1) | 30 |
| Example 39 | (3) | Absence | Presence | Absence | 45 | Aqueous Alkali Solution (1) | 25 |
| Example 40 | (4) | Absence | Presence | Absence | 45 | Aqueous Alkali Solution (1) | 25 |
| Example 41 | (5) | Absence | Presence | Absence | 20 | Aqueous Alkali Solution (1) | 10 |
| Example 42 | (17) | Absence | Presence | Absence | 50 | Aqueous Alkali Solution (1) | 25 |
| Example 43 | (18) | Absence | Presence | Absence | 20 | Aqueous Alkali Solution (1) | 10 |
| Comparative | Liquid Adhesive Composition | Absence | Presence | Absence | 30 | Aqueous Alkali Solution (1) | 30 |
| Example 1 | (1) for Comparative Example | | | | | | |
| Comparative | Liquid Adhesive Composition | Absence | Presence | Absence | 0.1 | Aqueous Alkali Solution (1) | 0.1 |
| Example 2 | (2) for Comparative Example | | | | | | |
| Comparative | Liquid Adhesive Composition | Absence | Presence | Absence | 0.1 | Aqueous Alkali Solution (1) | 0.1 |
| Example 3 | (3) for Comparative Example | | | | | | |

As described above, it can be seen that a good balance between the adhesion property and the releasing property can be achieved by using the temporary adhesive according to the invention as in the examples, although the adhesion property is achieved but the releasing property is insufficient in Comparative Example 1 and the adhesion property is insufficient in Comparative Examples 2 and 3.

Thus, the temporary adhesive according to the invention not only can temporarily support a member to be processed (for example, a semiconductor wafer) firmly when the member to be processed is subjected to a mechanical or chemical processing but also can easily release the temporary support for the member processed without imparting damage to the member processed.

Also, the region exposed to light in the adhesive layer formed through the exposure process did not exhibit the adhesion property at all. Since the adhesive support capable of adhering the member to be processed only by the outer peripheral portion of the adhesive layer thereof can be formed according to the technique, particularly, in the case where the member to be processed is a device wafer, when the adhesive support is released from the device wafer, it is possible to reduce damage of the inner portion of the device wafer. Heretofore, in order to form such a temporary adhesive which adheres only the outer peripheral portion, a large number of steps are necessary for forming the adhesive support (see, JP-T-2011-510518), it can be understood that according to the method using the temporary adhesive according to the invention described above, the adhesive support as described above can be simply formed only conducting pattern exposure.

### INDUSTRIAL APPLICABILITY

According to the invention, a temporary adhesive for production of semiconductor device, which not only can temporarily support a member to be processed (for example, a semiconductor wafer) firmly and easily when the member to be processed is subjected to a mechanical or chemical processing but also can easily release the temporary support for the member processed without imparting damage to the member processed, and an adhesive support and a production method of semiconductor device using the same can be provided.

Although the invention has been described in detail and by reference to specific embodiments, it is apparent to those skilled in the art that it is possible to add various alterations and modifications insofar as the alterations and modifications do not deviate from the spirit and the scope of the invention.

This application is based on a Japanese patent application filed on Jun. 13, 2012 (Japanese Patent Application No. 2012-134189), and the contents thereof are incorporated herein by reference.

### DESCRIPTION OF REFERENCE NUMERALS AND SIGNS

11, 11′, 21, 31: Adhesive layer
12: Carrier substrate
21A, 31A: Low adhesive region
21B, 31B: High adhesive region
40: Mask
41: Light-transmitting region
42: Light-shielding region
50: Active light or radiation
50′: Active light or radiation, or heat
60: Device wafer
60′: Thin device wafer
61: Silicon substrate
62: Device chip
63: Bump
70: Tape
100, 100′, 110, 120: Adhesive support

1. A temporary adhesive for production of semiconductor device, containing (A) a polymer compound having an acid group, (B) a diluent, and (C) a solvent.

2. The temporary adhesive for production of semiconductor device as claimed in claim 1, wherein the polymer compound (A) is a polyurethane resin having a carboxylic acid group, a (meth)acrylic polymer having a carboxylic acid group or a novolak resin having a carboxylic acid group.

3. The temporary adhesive for production of semiconductor device as claimed in claim 1, which further contains (D) a compound which generates a radical or an acid by irradiation of active light or radiation.

4. The temporary adhesive for production of semiconductor device as claimed in claim 1, which further contains (E) a compound which generates a radical or an acid by heat.

5. The temporary adhesive for production of semiconductor device as claimed in claim 4, wherein the compound (E) is an organic peroxide.

6. The temporary adhesive for production of semiconductor device as claimed in claim 3, wherein the diluent (B) is a reactive compound which is capable of being crosslinked by an action of a radical or an acid.

7. The temporary adhesive for production of semiconductor device as claimed in claim 1, which is for forming a through-silicon electrode.

8. An adhesive support comprising a substrate and an adhesive layer formed from the temporary adhesive for production of semiconductor device as claimed in claim 1.

9. A production method of semiconductor device having a member processed comprising:
adhering a first surface of a member to be processed to a substrate through an adhesive layer formed from the temporary adhesive for production of semiconductor device as claimed in claim 1;
conducting a mechanical or chemical processing on a second surface which is different from the first surface of the member to be processed to obtain the member processed; and
releasing the first surface of the member processed from the adhesive layer.

10. The production method of semiconductor device as claimed in claim 9, which further comprises irradiating active light or radiation, or heat to a surface of the adhesive layer which is to be adhered to the first surface of a member to be processed, before the adhering a first surface of a member to be processed to a substrate through the adhesive layer.

11. The production method of semiconductor device as claimed in claim 9, which further comprises heating the adhesive layer at a temperature from 50 to 300° C., after the adhering a first surface of a member to be processed to a substrate through the adhesive layer and before the conducting a mechanical or chemical processing on a second surface which is different from the first surface of the member to be processed to obtain the member processed.

12. The production method of semiconductor device as claimed in claim 9, wherein the releasing the first surface of the member processed from the adhesive layer comprises bringing the adhesive layer into contact with an aqueous alkali solution or a release solvent.

13. The production method of semiconductor device as claimed in claim 12, wherein the aqueous alkali solution contains a surfactant in an amount from 0.1 to 20% by weight based on a total weight of the aqueous alkali solution.

14. The production method of semiconductor device as claimed in claim 12, wherein the release solvent is acetone, anisole, cyclohexanone, ethanolamine, hexane, N-methyl-2-pyrrolidone or a fluorine-based solvent.
